(19) United States
(12) Patent Application Publication
(10) Pub. No.: US 2018/0066810 A1
(43) Pub. Date: Mar. 8, 2018

(54) ILLUMINATING APPARATUS

(71) Applicant: Telebrands Corp., Fairfield, NJ (US)

(72) Inventors: Lou Lentine, Chattanooga, TN (US); Erwin Lau, Fremont, CA (US); Alex Krause, Los Angeles, CA (US); Matthew Pooley, White Plains, NY (US); Edward Fei, Mountain View, CA (US); Patrick Murphy, Brooklyn, NY (US)

(21) Appl. No.: 15/796,268

(22) Filed: Oct. 27, 2017

Related U.S. Application Data
(63) Continuation-in-part of application No. 15/411,643, filed on Jan. 20, 2017.
(60) Provisional application No. 62/281,074, filed on Jan. 20, 2016.
(60) Provisional application No. 62/311,776, filed on Mar. 22, 2016.

(51) Int. Cl. F21K 9/64; F21V 9/16; H01S 5/40; F21V 7/06

(52) U.S. Cl. CPC F21K 9/64; F21V 9/16; F21Y 2115/10; H01S 5/4075; F21V 7/06; H01S 5/4012

(57) ABSTRACT

Light apparatuses including a light source generating a blue-colored light, a phosphorus filter transforming the blue-colored light into white light, and a light dispersing element receiving the light and projecting a plurality of discrete points of light onto a target surface that have been transformed into white light by the phosphorus filter. Methods for creating a plurality of discrete points of light on a target surface using a light apparatus including a light source and a phosphorus filter and a light dispersing element, including generating a light using the light source, in which the generated light is blue-colored light, transforming the light into white light by passing the light through a phosphorus filter, and causing the light to be incident on the light dispersing element, such that the light dispersing element disperses the light and creates a plurality of individual points of light on the target surface.

### CROSS-REFERENCE TO PRIOR APPLICATIONS

This application is a continuation-in-part of U.S. Non-Provisional application Ser. No. 15/411,643, filed on Jan. 20, 2017. This application claims priority to U.S. Non-Provisional application Ser. No. 15/411,643, filed on Jan. 20, 2017, U.S. Provisional Application Ser. No. 62/281,074, filed on Jan. 20, 2016, and U.S. Provisional Application Ser. No. 62/311,776, filed on Mar. 22, 2016. All of the foregoing applications are hereby incorporated by reference herein in their entireties.

### FIELD

The present invention generally relates to an illuminating/lighting apparatus. Specifically, embodiments of the present invention relate to an illuminating/lighting apparatus configured to produce white light by passing blue light through a filter.

### BACKGROUND

Lighting is often used in a decorative manner. For example, many people decorate homes, offices, stores, outdoor spaces, etc. with various lighting to achieve certain effects, designs, atmospheres, festive moods, etc. Although decorative lighting may be used at any time of the year, many people utilize decorative lighting during certain holidays.

Decorative lighting comes in many different types and colors. For example, string lights, character lights, and laser lights are just a few of the various forms of decorative lighting with red, green, blue and white being some common colors. However, creating white light for decorative lighting can be difficult in certain circumstances. Creating decorative lighting capable of achieving some effects and characteristics can require consideration of a range of engineering factors such as mixing of combined light sources and projection of the desired display. For example, creating decorative lighting capable of emitting white light can present difficulties in combining sources to produce the white light while maintaining certain characteristics of the light, such as divergence.

### SUMMARY

Embodiments of the present invention can provide a laser or other light apparatus including at least one light source generating a light having a blue color, and at least one light filter configured such that the blue-colored light passes through this filter thereby producing a white light. In additional embodiments, the light source may be a laser light source or an LED light source. In further embodiments, the blue-colored light may have a wavelength of 450 nm, approximately 450 nm, or 445 nm-455 nm. It will be understood that the expression “blue-colored light” as used herein may refer, collectively and individually, to a light having a blue appearance, to a light having a wavelength of 450 nm, to a light having a wavelength of approximately 450 nm, and to a light having a wavelength of 445 nm-455 nm. In yet further embodiments, the filter may incorporate phosphorus to effect the production of white light from blue-colored light, for example, such that the filter may be a fluorescent phosphorus-coated optical element or a phosphorus-coated film or a phosphorus film. It will be understood that the expression “phosphorus filter” as used herein may refer, collectively and individually, to a filter, film or any other optical element incorporating or made from phosphorus which uses the phosphorus to manipulated blue-colored light to produce white light. It will be understood that the white light need not be perfectly white but rather may approximate white light to within manufacturing and/or acceptable deviation tolerances as may be understood by one of ordinary skill in the art.

Embodiments of the present invention can provide a laser light apparatus including a first laser light source generating a first light having a first color, a second laser light source generating a second light having a second color, a light combining assembly configured to combine the first light and the second light to generate a combined light, and a parabolic light dispersing element receiving the combined light and projecting an output onto a target surface. In additional embodiments of the invention, one or more of the first light, the second light and/or the combined light are a blue-colored light. In further embodiments, the blue-colored light passes through a phosphorus filter thereby generating a white light. The output can include a plurality of discrete points of light projected onto the target surface.

According to certain embodiments, the laser light apparatus can further include a third laser light source generating a third light having a third color, and where the light combining assembly can be further configured to combine the third light with the first light and the second light to generate the combined light. In additional embodiments of the invention, one or more of the first light, the second light, the third light and/or the combined light are a blue-colored light. In further embodiments, the blue-colored light passes through a phosphorus filter thereby generating a white light. Further, a color of the combined light can include white, and/or the first color can include red, the second color can include green, and the third color can include blue.

According to certain embodiments, the laser light apparatus can include an aperture through which the light dispersing element projects the output, and the aperture may be disposed substantially at a focus of the parabolic reflector. In additional embodiments of the invention, a phosphorus filter may be disposed at or in the vicinity of or incorporated into the aperture. The laser light apparatus can further include a beam expanding element configured to expand a diameter of at least one of the first light, the second light, and the combined light.

According to certain aspects, the parabolic light dispersing element can include a faceted parabolic reflector and the light combining assembly can include at least one of a multi-chroic mirror, a pair of gratings, a reflector, a prism, and a beam splitter. In additional embodiments of the invention, a phosphorus filter may be disposed at or in the vicinity of or incorporated into the parabolic light dispersing element, the faceted parabolic reflector, the light combining assembly, the multi-chroic mirror, the pair of gratings, the reflector, the prism, or the beam splitter. Further, the first laser light source, the second laser light source, and the parabolic light dispensing element, and, in certain embodiments, the phosphorus filter, can be housed within a common housing.

Another embodiment of the present invention can provide a laser light apparatus including a plurality of laser light sources each generating a light, each of the lights having an associated color, a light combining assembly configured to combine each of the lights generated by the plurality of laser light sources and generate a combined light, a faceted parabolic reflector receiving the combined light and projecting an output onto a target surface, and an aperture disposed substantially at a focus of the faceted parabolic reflector, where the output can be projected out through the aperture and including a plurality of discrete points of light projected onto the target surface. In additional embodiments of the invention, one or more of the lights generated by the plurality of laser light sources and/or the combined light are a blue-colored light. In further embodiments, a phosphorus filter may be disposed at or in the vicinity of or incorporated into the laser light sources, the light combining assembly, the faceted parabolic reflector, and the aperture.

The plurality of laser light sources can generate a first light including a red color, a second light including a green color, and a third light including a blue color, and a color of the combined light can include white.

Further, the laser light apparatus can further include a beam expanding element configured to expand a diameter of at least one of the lights generated by the plurality of laser light sources and the combined light the light combining assembly can include at least one of a multi-chroic mirror, a pair of gratings, a reflector, a prism, and a beam splitter. In additional embodiments of the invention, a phosphorus filter may be disposed at or in the vicinity of or incorporated into the beam expanding element, the light combining assembly, the multi-chroic mirror, the pair of gratings, the reflector, the prism, or the beam splitter.

Yet another embodiment of the present invention can provide a lighting apparatus including a light source producing a light, which, in certain embodiments, may be a blue-colored light, and a parabolic light dispersing element. In additional embodiments, the blue-colored light may pass through a phosphorus filter thereby generating a white light. The light produced by the light source can be incident on the light dispersing element and the light dispersing element can output a plurality of discrete points of light such that the lighting apparatus projects the plurality of discrete points of light onto a target surface. In yet further embodiments of the invention, the phosphorus filter may be disposed at or in the vicinity of or incorporated into the light source or the parabolic light dispersing element.

The light source can include a plurality of light emitting diodes (LEDs). In additional embodiments of the invention, one or more or all of the LEDs generate a blue-colored light. In additional embodiments, a plurality of the LEDS generate light that when combined becomes a blue-colored light. The plurality of LEDs can be arranged in an offset arrangement, with each of the plurality of LEDs producing light at an offset angle relative to the parabolic light dispersing element. Further, the light source can include a light pipe assembly configured to combine light produced by at least two of the plurality of LEDs. In further embodiments, a phosphorus filter may be disposed at or in the vicinity of or incorporated into the LEDs, the parabolic light dispersing element or the light pipe assembly.

According to certain aspects, lighting apparatus can include an aperture disposed substantially at a focus of the parabolic light dispersing element and/or the light dispersing element can include a faceted parabolic reflector. In further embodiments, a phosphorus filter may be disposed at or in the vicinity of or incorporated into the aperture or the faceted parabolic reflector. Further, the light source and the parabolic light dispersing element, and, in certain embodiments, the phosphorus filter, can be housed in a common housing.

Yet another embodiment of the present invention can provide a method for creating a plurality of discrete points of light on a target surface using a lighting apparatus including a light source and a parabolic light dispersing element. The method can include generating a light, which may, in certain embodiments, be a blue-colored light, using the light source, and causing the light to be incident on the parabolic light dispersing element, such that the parabolic light dispersing element reflects the light and creates a plurality of individual points of light on the target surface. In certain embodiments, the blue-colored light may pass through a phosphorus filter, and, in further embodiments, the phosphorus filter may be disposed at or in the vicinity of or incorporated into the light source or the parabolic light dispersing element.

Further, the light source can include a plurality of lasers each generating a laser light, and each of the laser lights can be combined to form the light. In additional embodiments, one or more or all of the lasers generates a blue-colored light, and/or the combined light is a blue-colored light. According to certain aspects, the parabolic light dispersing element can reflect the light out through an aperture disposed substantially at a focus of the parabolic light dispersing element, and the parabolic light dispersing can include a faceted parabolic reflector. Further, the light source and the parabolic light dispersing element can be housed in a common housing. In further embodiments, a phosphorus filter may be disposed at or in the vicinity of or incorporated into the lasers, the parabolic light dispersing element, the aperture or the faceted parabolic reflector. In yet further embodiments, the phosphorus filter may be additionally housed in the common housing.

According to certain embodiments, the light source can include a light-emitting diode (LED), which can include an LED array and/or a plurality of LED arranged in an offset arrangement. In additional embodiments, one or more or all of the LEDs generates a blue-colored light. In further embodiments, the blue-colored light passes through a phosphorus filter, thereby generating a white light.

### BRIEF DESCRIPTION OF THE DRAWINGS

The features and advantages of the present invention can be more readily understood from the following detailed description with reference to the accompanying drawings, wherein:

FIG. 1 is a block diagram of an exemplary illuminating/lighting apparatus according to one embodiment of the present invention;

FIG. 2A is a block diagram of an exemplary light source of an exemplary illuminating/lighting apparatus according to one embodiment of the present invention;

FIG. 2B is a block diagram of an exemplary light source of an exemplary illuminating/lighting apparatus according to one embodiment of the present invention;

FIG. 2C is a block diagram of an exemplary light source of an exemplary illuminating/lighting apparatus according to one embodiment of the present invention;

FIG. 2D is an illustration of an exemplary beam expander, comprising of a diverging and a collimating lens, of an exemplary illuminating/lighting apparatus according to one embodiment of the present invention;

FIG. 3A is a block diagram of an exemplary light source of an exemplary illuminating/lighting apparatus according to one embodiment of the present invention;

FIG. 3B is a block diagram of an exemplary light source of an exemplary illuminating/lighting apparatus according to one embodiment of the present invention;

FIG. 3C is a diagram of an exemplary light source of an exemplary illuminating/lighting apparatus according to one embodiment of the present invention;

FIG. 3D is a diagram of an exemplary light source of an exemplary illuminating/lighting apparatus according to one embodiment of the present invention;

FIG. 3E is a diagram of an exemplary light source of an exemplary illuminating/lighting apparatus according to one embodiment of the present invention;

FIG. 4A is a graph showing the colors that may be produced by an exemplary two laser system of an exemplary illuminating/lighting apparatus according to one embodiment of the present invention;

FIG. 4B is a graph showing the colors that may be produced by an exemplary three laser system of an exemplary illuminating/lighting apparatus according to one embodiment of the present invention;

FIGS. 5A, 5B and 5C are illustrations of various laser mounting apparatuses according to one embodiment of the present invention;

FIG. 6 is a block diagram of an exemplary light source of an exemplary illuminating/lighting apparatus according to one embodiment of the present invention;

FIG. 7A is a diagram of an exemplary illuminating/lighting apparatus according to one embodiment of the present invention;

FIG. 7B is a diagram of an exemplary illuminating/lighting apparatus according to one embodiment of the present invention;

FIG. 7C is a diagram of an exemplary illuminating/lighting apparatus according to one embodiment of the present invention;

FIG. 8A is a diagram of an exemplary light source of an exemplary illuminating/lighting apparatus according to one embodiment of the present invention;

FIG. 8B is a diagram of an exemplary light source of an exemplary illuminating/lighting apparatus according to one embodiment of the present invention;

FIG. 8C is a diagram of an exemplary light source of an exemplary illuminating/lighting apparatus according to one embodiment of the present invention;

FIG. 8D is a diagram of an exemplary light source and light dispersing element of an exemplary illuminating/lighting apparatus according to one embodiment of the present invention;

FIG. 8E is a diagram of an exemplary light source of an exemplary illuminating/lighting apparatus according to one embodiment of the present invention;

FIG. 9 is an illustration of an exemplary multi-faceted parabolic mirror of an exemplary illuminating/lighting apparatus according to one embodiment of the present invention;

FIGS. 10A and 10B are illustrations of the trajectory of light rays reflected from a reflecting element of an exemplary illuminating/lighting apparatus according to one embodiment of the present invention;

FIG. 11 is an illustration of exemplary diffraction gratings of an exemplary illuminating/lighting apparatus according to one embodiment of the present invention;

FIG. 12 is a block diagram of an exemplary illuminating/lighting apparatus with a light source producing blue-colored light and a phosphorus filter, according to one embodiment of the present invention;

FIG. 13 is a block diagram of an exemplary light source of an exemplary illuminating/lighting apparatus according to one embodiment of the present invention; and

FIG. 14 is a diagram, with exploded and unexploded views, of an exemplary illuminating/lighting apparatus according to one embodiment of the present invention.

### DETAILED DESCRIPTION

Embodiments of the present invention generally relate to an illuminating/lighting apparatus. Specifically, certain exemplary embodiments of the present invention provide various new and novel features for an illuminating/lighting lighting apparatus using laser(s) and/or light emitting diode(s) (LED), which in some embodiments emit blue-colored light, which can be passed through a phosphorus filter to produce a white light, as a light source to project a plurality of white discrete points of light on a target surface. Although the embodiments of the present invention are primarily described with respect to an illuminating/lighting apparatus generating a white light, it is not limited thereto, and it should be noted that the exemplary apparatus and systems described herein may be used in connection with any illuminating/lighting lighting apparatus generating other color lights.

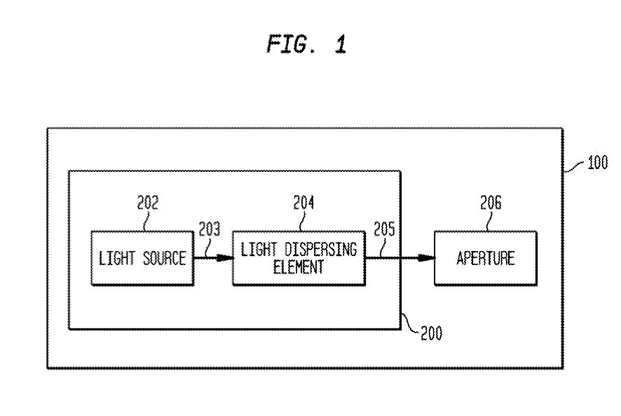

In accordance with embodiments of the present invention, FIG. 1 shows a block diagram representation of illuminating/lighting apparatus 100. As shown in FIG. 1, illuminating/lighting apparatus 100 may include a light assembly 200 and an aperture 206. Light assembly 200 may include light source 202 and light dispersing element 204. As shown in FIG. 1, light source 202 may produce light 203, which in some embodiments may be blue-colored light that can be passed through a phosphorus filter to produce a white light, which is received and manipulated by light dispersing element 204, which then outputs light 205 through aperture 206. In certain embodiments, the light may pass through a phosphorus filter, which may be positioned for example, at or in the vicinity of light source 202, light dispersing element 204, and/or aperture 206, or anywhere along the path through which the light may travel. Light source 202 may include any type of light source that is capable of producing the desired light. For example, light source 202 may be designed so as to produce light having a certain color, a certain power or intensity, or certain angular divergence properties. According to certain embodiments of the present invention, light source 202 may enable illuminating/lighting apparatus 100 to project a light having an optical power of greater than or equal to 20 milliwatts that is sufficiently collimated to travel 15.2 meters (50 feet) without undue degradation of the intended projection pattern. According to certain exemplary embodiments, light source 202 may include one or more lasers, LED, LED lamps, halogen bulbs, high-intensity discharge gas lamps, fiber optic lighting systems, or any other mechanism capable of producing light. Light dispersing element 204 preferably receives light 203 from light source 202 and manipulates and conditions the received light to a desired output light. According to certain exemplary embodiments of the present invention, light dispersing element 204 receives light 203 from light source 202 and creates a plurality of discrete points of light, which may be output by illuminating/lighting apparatus 100 through aperture 206 onto a target surface. Light dispersing element 204 may include any mechanism by which light 203 produced by light source 202 may be dispersed and/or manipulated and projected out of illuminating/lighting apparatus 100. For example, light dispersing element 204 may include a mirror, lens, reflector, diffraction grating, refractor, prism, charged-coupled device, microlens array, color wheel, or any other optical element capable of dispersing or manipulating light. In certain embodiments, the phosphorus filter may be positioned at or in the vicinity any of these components, or anywhere along the path through which the light may travel.

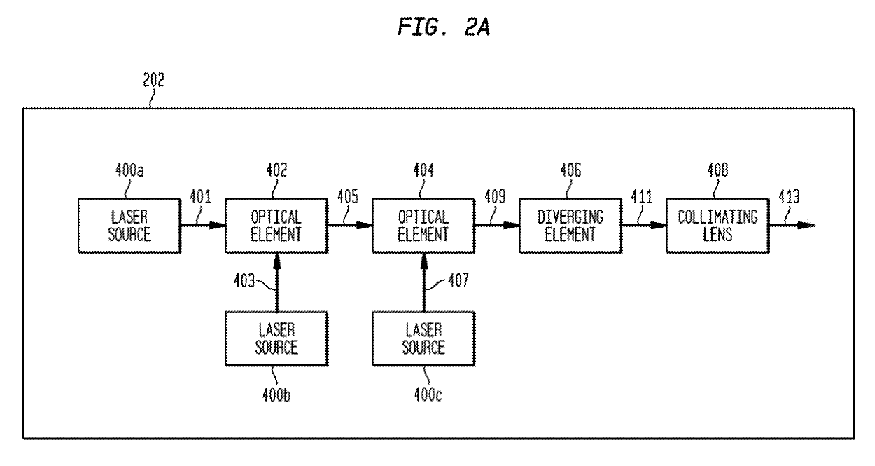

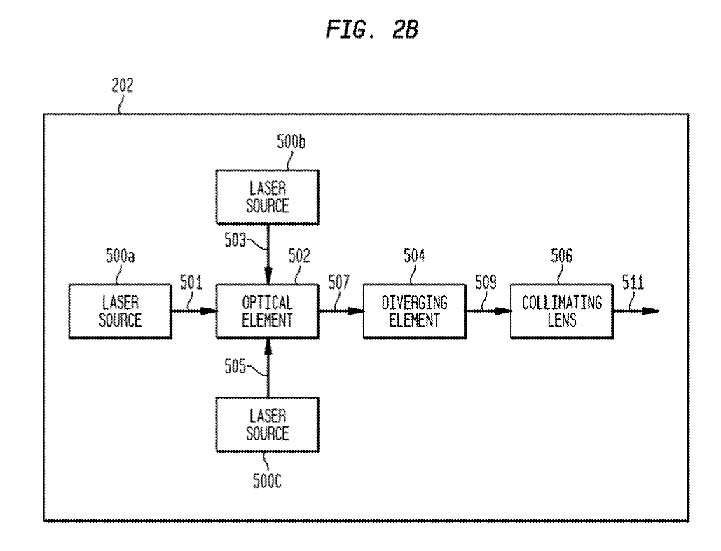

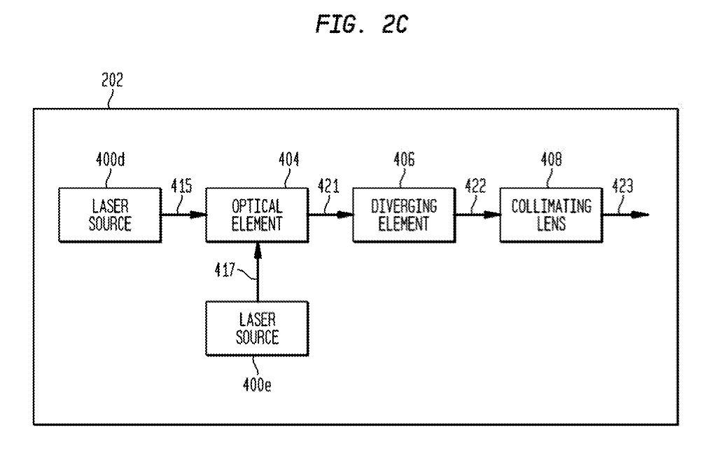

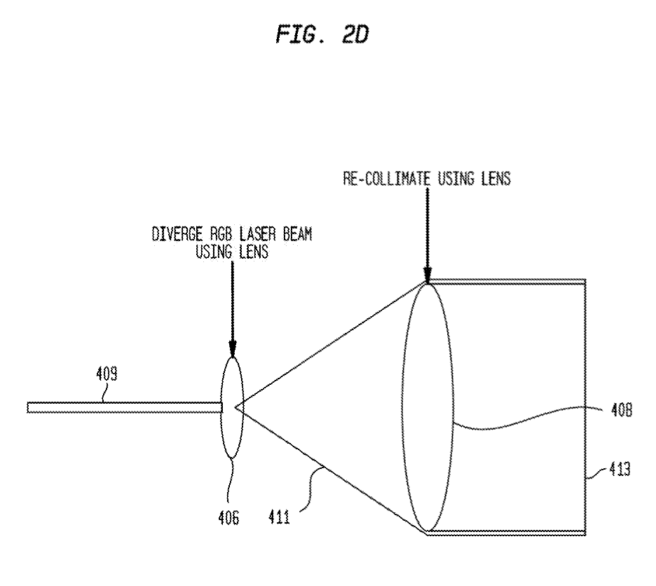

FIGS. 2A and 2B are block diagrams of light source 202 according to embodiments of the present invention. As shown in FIG. 2A, light source 202 may include sources 400a, 400b, 400c, optical elements 402, 404, diverging element 406, and collimating lens 408. In certain embodiments, one or more or all of the sources may emit blue-colored light that can be passed through a phosphorus filter to obtain a white light. Although FIG. 2A shows light source 202 having three sources, various optical elements, a diverging element, and a collimating lens, light source 202 may include any number of sources and other components depending on the desired characteristics of the light that is to be output by light source 202. For example, the color, wavelength, intensity, brightness, power, shape, pattern, etc. of the light produced by illuminating/lighting apparatus 100 may be customized using various designs and configurations of various components of light source 202. A phosphorus filter may, in some embodiments, be positioned at or in the vicinity of the light sources, optical elements, diverging element, and/or collimating lens.

As shown in FIG. 2A, light source 202 may include three laser sources 400a, 400b, and 400c, which produce light 401, 403, and 407, respectively. Light 401, 403, 407 produced by laser sources 400a, 400b, and 400c may be conditioned, manipulated, and combined by optical elements 402, 404, diverging element 406, and collimating lens 408 to generate the light output by light source 202. For example, optical element 402 may combine light 401 generated by laser source 400a and light 403 generated by laser source 400b to produce output light 405. Optical element 404 may then combine light 405, which is output by optical element 402, with light 407 generated by laser source 400c to produce output light 409. In some embodiments, the light may be combined to form a blue-colored light, and the blue-colored light can be passed through a phosphorus filter. In certain embodiments, the output light is a blue-colored light passing through a phosphorus filter, which can produce a white light.

Output light 409 from optical element 404 may be incident on diverging element 406, which may increase the divergence of light 409. Diverging element 406 can include any such element that can increase the divergence of light incident upon it, and may include, for example, a diverging lens, a diverging mirror, a prism, a filter, an aperture or any other type of optical element capable of increasing the divergence of a beam of light. In some embodiments, a phosphorus filter may be positioned at or in the vicinity of the diverging element, the diverging lens, the diverging mirror, the prism, the filter, the aperture or other optical element. Light 411 output by diverging element 406 may be incident on collimating lens 408 which may narrow the divergence angle of light 411 and output light 413. For example, narrowing the divergence angle of the light can include causing the direction of the light to become more aligned or making the cross section of the beam smaller. Collimating lens 408 can include any such element that can narrow the light appropriately, and can include, for example, a mirror, lens or aperture or any other optical element capable of collimating light. In some embodiments, a phosphorus filter may be positioned at or in the vicinity of the collimating lens, the mirror, the lens, the aperture or other optical element.

According to one exemplary embodiment, laser sources 400a, 400b, 400c may generate a red light, a green light, and/or a blue light, respectively. For example, laser source 400a may generate light 401 which may be red, laser source 400b may generate light 403 which may be green, and laser source 400c may generate light 407 which may be blue. According to certain exemplary embodiments, laser source 400a may generate a coherent beam of red light with a wavelength of approximately 638 nm, laser source 400b may generate a coherent beam of green light with a wavelength of approximately 520 nm and laser source 400c may generate a coherent beam of blue light with a wavelength of approximately 450 nm. In operation, optical element 402 may combine light 401 generated by laser source 400a with light 403 generated by source 400b, and optical element 404 may then combine light 405 output by optical element 402 with light 407 generated by source 400c, thereby generating light 409. According to certain exemplary embodiments, the combination of red, green, and blue light may result in output light 409 being white. Alternatively, the color of light sources 400a, 400b, and 400c can be selected to obtain any color or shade of output light, such as blue, purple, yellow, orange, etc. In one embodiment the color of light sources 400a, 400b, and 400c can be selected to obtain a blue-colored light. Light 409 produced by optical element 404 may then be further manipulated and/or conditioned by diverging element 406 and collimating lens 408. In certain embodiments, a blue-colored light passes through a phosphorus filter, which may be positioned, for example, at or in the vicinity of the diverging element 406 or collimating lens 408.

According to certain exemplary embodiments, optical elements 402 and 404 may include a dichroic mirror. In an exemplary embodiment where optical elements 402 and 404 include dichroic mirrors, optical element 402 may allow light 401 generated by laser source 400a to pass through while reflecting light 403 generated by laser source 400b at an angle such that the light passing through optical element 402 (which was generated by laser source 400a) and the light reflected by optical element 402 (which was generated by laser source 400b) is thereby combined into light 405. In certain embodiments, one or more or all of these lights are a blue-colored light, which, in yet further embodiments, may pass through a phosphorus filter. The resulting combined light 405 may then be incident on optical element 404. Similarly, optical element 404 may allow light 405 output by optical element 402 to pass through while reflecting light 407 generated by laser source 400c at an angle such that light 405 passing through optical element 404 (which was the combined light output by optical element 402) and light 407 reflected by optical element 404 (which was generated by laser source 400c) are thereby combined into light 409 which goes on to be incident on diverging element 406. Alternatively, optical elements 402 and 404 may include a dichroic filter, a beam splitter, an absorption filter array, a dichroic prism, or any other type of optical element. Alternatively, the various source can be combined using, for example, a pair of parallel gratings, parabolic/shaped reflectors, polarized beam splitters to combine orthogonally polarized beams, etc. In certain embodiments, a phosphorus filter may be positioned at or in the vicinity of any of these optical elements.

FIG. 2B shows light source 202 according to another embodiment of the present invention. Although similar to light source 202 shown in FIG. 2A, light source 202 shown in FIG. 2B includes a single optical element 502 in place of optical elements 402 and 404. Nevertheless, light source 202 shown in FIG. 2B functions substantially similar to light source 202 shown in FIG. 2A. In certain embodiments, light source 202 may produce a blue-colored light. Light 501, 503, 505 from laser sources 500a, 500b, 500c may be incident on optical element 502, which may combine light 501, 503, 505 generated by light sources 500a, 500b, and 500c into output light 507. In certain embodiments one or more or all of these lights may be a blue-colored light. Similar to light source 202 shown in FIG. 2A, light 507 output by optical element 502 may be expanded by diverging element 504 and then collimated by collimating lens 506. Optical element 502 may include a trichroic mirror, a cross dichroic prism, a beam splitter, a miniaturized RGB-Combiner or any other type of optical element capable of combining at least three sources of light. In some embodiments, a phosphorus filter may be positioned at or in the vicinity of, or between the diverging element, collimating lens, trichroic mirror, cross dichroic prism, beam splitter, miniaturized RGB-combiner or other optical element.

Although FIGS. 2A and 2B show light source 202 having three laser sources, other embodiments contemplate light source 202 having any number of laser sources. For example, light source 202 may include less than three laser sources, such as a single laser source or two laser sources, or more than three laser sources, such as four, five, six, or more laser sources. One or more or all of these light sources may produce a blue-colored light. Accordingly, the design of light source 202 (e.g., the number and design of laser sources as well as the number and design of the various optical elements) can be modified depending on the desired output light being generated by light source 202. In certain embodiments, the output light may be a blue-colored light, and may pass through a phosphorus filter to create white light.

FIG. 2C shows a block diagram of light source 202 including two laser sources 400d and 400e, which produce light 415, and 417, respectively. According to one exemplary embodiment, laser sources 400d and 400e may generate any one of a red light, a green light, a blue light and/or a cyan light. In certain embodiments, one or more or all of the laser sources generate a blue-colored light. According to certain exemplary embodiments, laser sources 400d and 400e may generate light 415, which may be green light having a wavelength of approximately 520 nm and light 417, which may be blue light having a wavelength of approximately 450 nm, respectively. In another embodiment of the present invention, laser sources 400d and 400e may generate light 415, which may be blue/cyan light having a wavelength of approximately 488 nm and light 417, which may be red having a wavelength of approximately 635 nm, respectively. The light produced by each of laser sources 400d and 400e may be conditioned, manipulated, and combined by optical element 404, diverging element 406, and collimating lens 408 to generate light 423 output by light source 202. Similar to light source 202 shown in FIGS. 2A and 2B, optical element 404 may combine light 415, which is output by laser source 400d, with light 417 generated by laser source 400e to produce light 421. Light 421 output from optical element 404 may be incident on diverging element 406, which may expand light 421 by expanding the diameter of light 421 incident on diverging element 406. Diverging element 406 can include any such element that can expand the light incident on it, and may include, for example, a diverging lens, a diverging mirror, a prism, a filter, an aperture or any other type of optical element capable of increasing the divergence of a beam of light. Diverging light 422 output by diverging lens 406 may be incident on collimating lens 408 which may narrow the light and output light 423. For example, narrowing the light can include causing the direction of the light to become more aligned or making the cross section of the beam to become smaller. Collimating lens 408 can include any such element that can narrow the light appropriately, and can include, for example a mirror, lens or aperture or any other optical element capable of collimating light. In certain embodiments, blue-colored light passes through a phosphorus filter, which may be positioned at or in the vicinity of the light sources, optical element, diverging element, diverging lens, diverging mirror, prism, filter, aperture, or collimating lens (including the mirror, lens or aperture or other optical element of such collimating lens).

According to certain embodiments of the present invention, the combination of light 419 and 417 may generate a white output light 421. Alternatively, light sources 400d and 400e can be selected to obtain any color or shade of output light, such as blue, purple, yellow, orange, etc. In certain embodiments, the light sources are selected so as to obtain a blue-colored light. Light 421 produced by optical element 404 may then be further manipulated and/or conditioned by diverging element 406 and collimating lens 408. In some embodiments, the blue-colored light is further manipulated and/or conditioned by passing through a phosphorus filter, thereby producing a white light. Such phosphorus filter may be positioned at or in the vicinity of, the light sources, the output light, diverging element or collimating lens.

Similar to light source 202 shown in FIG. 2A, optical element 404 may include a dichroic mirror. In an exemplary embodiment where optical element 404 includes a dichroic mirror, optical element 404 may allow light 415 output by laser source 400d to pass through while reflecting light 417 generated by laser source 400e at an angle such that light 415 generated by source 400d and light 417 reflected by optical element 404 (which was generated by laser source 400e) is thereby combined into light 421 which goes on to be incident on diverging element 406. Alternatively, optical element 404 may include a dichroic filter, a beam splitter, an absorption filter array, a dichroic prism, or any other type of optical element. In some embodiments, light 421 may be a blue-colored light and pass through a phosphorus filter, which phosphorus filter may be positioned in the path of light 421, for example, at or in the vicinity of any of the foregoing elements through which light 421 passes or is manipulated or conditioned.

FIG. 2D shows an exemplary beam expander (which can include, e.g., a diverging element and a collimating lens) in further detail. A beam expander typically inputs a collimated beam with a certain beam waist and outputs a collimated beam with a wider beam waist. A beam expander can include a series of lenses that can, for example, focus a beam, diverge a beam, collimate a beam, etc. For example, a beam expander may expand a beam by a combination of a diverging element followed by a converging element, such as a collimating lens. The exemplary beam expander may include diverging element 406, which may include a diverging lens, and collimating lens 408. Diverging element 406 may diverge a beam by increasing the divergence angle of the collimated beam of light incident upon it. As shown in FIG. 2D, an input light 409, which may include, for example, light produced by light source 202, may be incident on diverging element 406. In certain embodiments, input light may be a blue-colored light. Diverging element 406 may diverge light 409, thereby transforming the collimated input beam 409 into the diverging beam 411. Diverging light 411 may then be incident on collimating lens 408 to re-collimate diverging light 411 to output collimated light 413 that has a beam diameter that is larger than that of collimated beam 409. During the re-collimation of light 411, diffraction may result around the edge of collimating lens 408. In exemplary embodiments where light 409 includes a white light made from a combination of red, green and blue light, diffraction around the edge of collimating lens 408 may result in the red, green, and blue light separating, which may result in chromatic aberrations. In certain embodiments, where a blue-colored light is present, it may pass through a phosphorus filter, thereby being transformed into a white light. The phosphorus filter may be positioned at or in the vicinity of the light source, the beam expander, the diverging element, the converging element or the collimating lens.

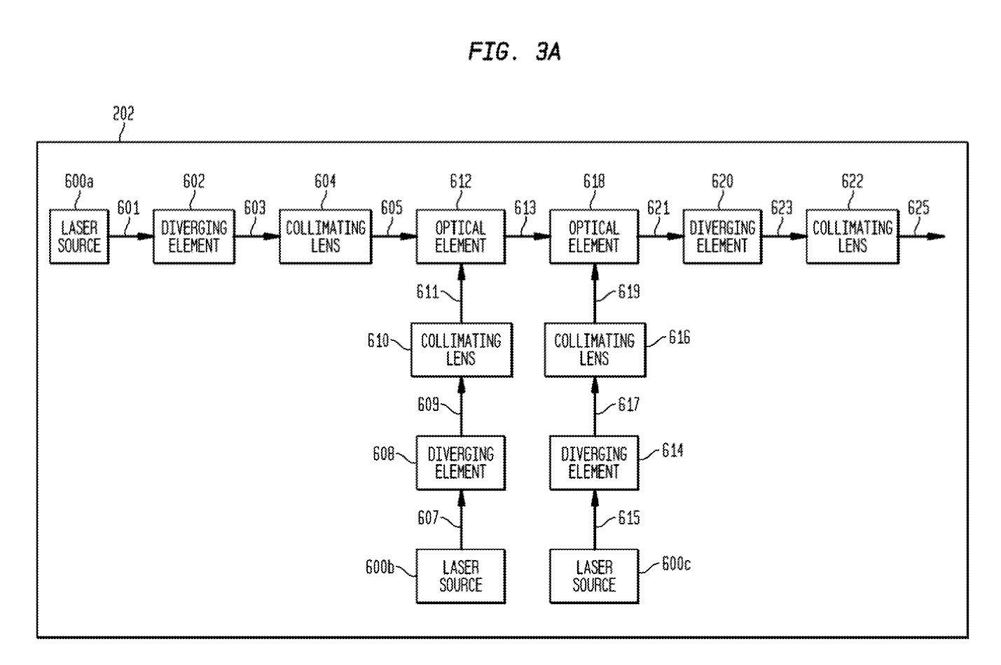

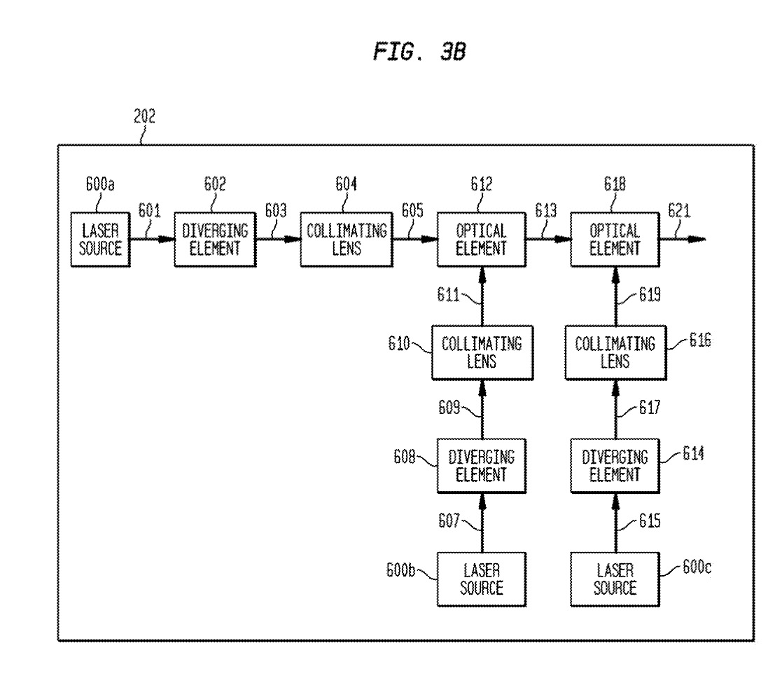

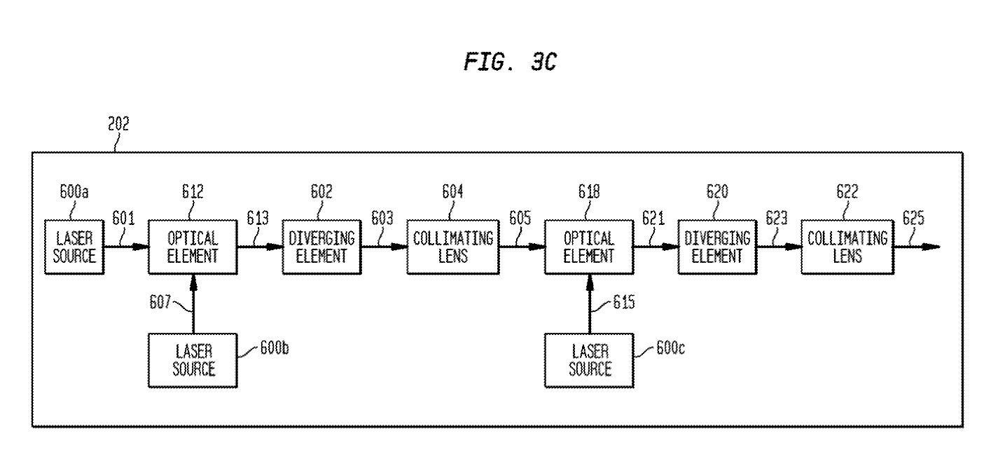

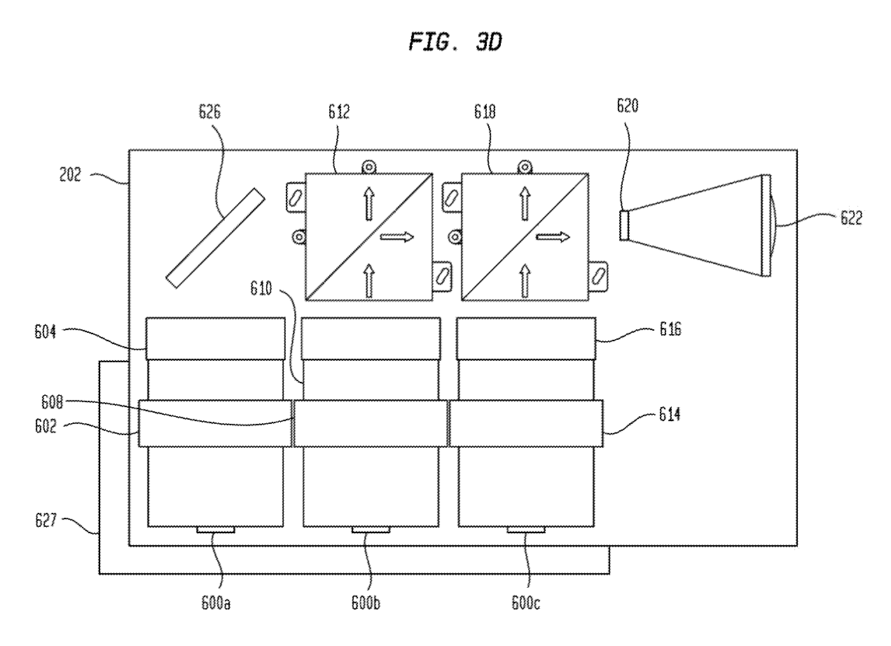

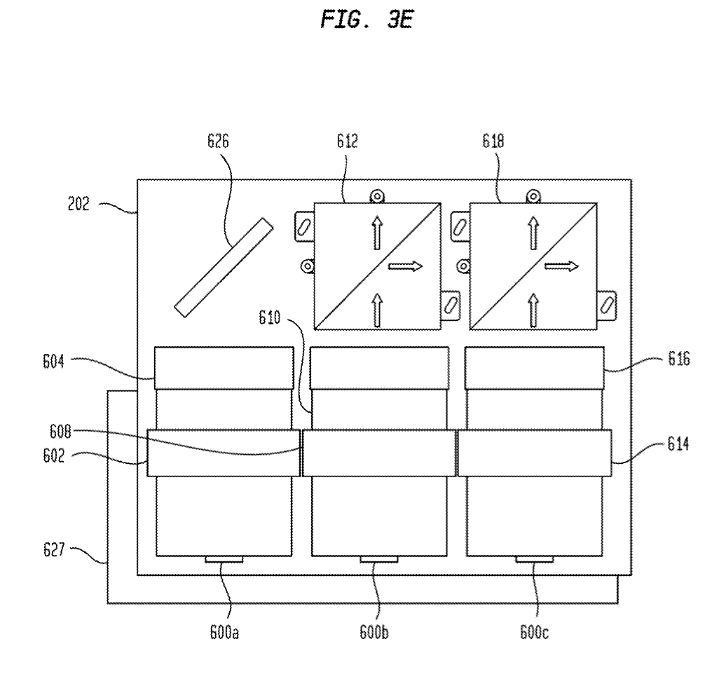

FIGS. 3A,3B, and 3C show embodiments of light source 202 according to further embodiments of the present invention. Although light sources 202 shown in FIGS. 3A and 3B are similar to those described with respect to FIGS. 2A, 2B, and 2C, as shown in FIGS. 3A and 3B (and, in certain embodiments, one or more or all of these light sources may produce blue-colored light), light source 202 includes initial diverging elements 602, 608, 614 and collimating lenses 604, 610, 616 at sources 600a, 600b, 600c prior to the combination of the light by their respective optical elements 612 and 618. This configuration, for example, enables combination of larger beams of light, which can, for example, alleviate some tolerance requirements. Specifically, this configuration reduces position alignment tolerances and reduces tolerances related to the divergence of the three beams of light producing a combination beam of white light. As shown in FIGS. 3A and 3B, source 600a may generate light 601 that may be expanded by diverging element 602 and collimating lens 604. Diverging light 603 emitted by diverging element 602 may pass through collimating lens 604 to optical element 612. Source 600b may generate light 607, which may be expanded by diverging element 608 and collimating lens 610. The diverging light 609 emitted by diverging element 608 may pass through collimating lens 610 to optical element 612. Similarly, source 600c may generate light 615 that may be expanded by diverging element 614 and collimating lens 616. Diverging light 617 emitted by diverging element 614 may pass through collimating lens 616 to optical element 618. Diverging elements 602, 608, 614, and 620 may include a diverging lens, a diverging mirror, a prism, a filter, an aperture or any other type of optical element capable of expanding a beam of light. Light 623 from diverging element 620 may be incident on collimating lens 622 and exit light source 202. Collimating lens 604, 610, 616, and 622 may include a mirror, lens or aperture or any other optical element capable of collimating light. Similar to the configurations shown in FIGS. 2A, 2B and 2C, optical elements 612 and 618 may include a dichroic mirror, dichroic filter, a beam splitter, absorption filter array, dichroic prism, or any other type of filter element. In embodiments with a blue-colored light, that blue-colored light may pass through a phosphorus filter, which may be positioned, for example, at or in the vicinity of the light source, diverging element, collimating lens, optical element, diverging lens, diverging mirror, prism, filter, aperture or other beam-expanding optical element, mirror, lens, aperture, or other light collimating element, dichroic mirror, dichroic filter, beam splitter, absorption filter array, dichroic prism, or other filter element.

As shown in FIG. 3B, diverging element 620 and collimating lens 622, which are included in light source 202 shown in FIG. 3A, may not be necessary if the beam expansion performed by diverging elements 602, 608, 614 and collimating lenses 604, 610, 616, is sufficient to achieve a final desired beam diameter. In FIG. 3B, light 621 emitted from optical element 618 may not need be further expanded by a diverging element. Diverging elements 602, 608, 614 and collimating lenses 604, 610, 616, may sufficiently expand the light 601, 607, 615 emitted by laser sources 600a, 600b, 600c, respectively, to the desired beam diameter thereby removing the need for diverging element 620 and collimating lens 622. For example, sources 600a, 600b, 600c can produce light having any desired diameter which may be combined into light 621 having a sufficient diameter. Alternatively, light 601, 607, 615 may be expanded by diverging elements 602, 608, 614 and collimating lenses 604, 610, 616, to have a desired diameter then combined into light 621 having the desired diameter. For example, light 621 can have a diameter of 5 mm, 10, mm, 15 mm, 20 mm, 25 mm or any other diameter to create the desired output light.

FIG. 3C illustrates yet another embodiment of light source 202. As shown in FIG. 3C, sources 600a and 600b may generate light 601 and 607 that may strike optical element 612. Light 613 emitted from optical element 612 may be diverged by diverging element 602 and pass through collimating lens 604 to optical element 618, which may be combined with light 615 generated by source 600c. Light 621 may be diverged by diverging element 620, which may then be collimated by collimating lens 622, and thereby producing output light 625.

According to certain exemplary embodiments, the light produced by laser sources 400a, 400b, 400c, 400d, 400e, 500a, 500b, 500c, 600a, 600b and 600c may have a beam diameter of 1 mm prior to expansion. Diverging elements 406, 504, 602, 608, 614, 620, in combination with their respective collimating lens, may expand the initial beam diameter from 1 mm to up to 25 mm prior to the output light being incident on light dispersing element 204 (at which, in certain embodiments, a phosphorus filter may be positioned, which may transform blue-colored light into white light). Alternatively, sources 400a, 400b, 400c, 400e, 400d, 500a, 500b, 500c, 600a, 600b and 600c, diverging elements 406, 504, 602, 608, 614, 620, and collimating lenses 408, 506, 604, 610, 616, 622 can be selected to obtain any diameter output light.

Alternatively, in situations where light 601, 607, 615 generated by laser sources 600a, 600b, 600c may already have the desired beam width prior to entering collimating lens 604, 610, 616, diverging elements 602, 608, 614 may not be necessary. Accordingly, laser source 600a and collimating lens 604 may be integrated into a monolithic package, laser source 600b and collimating lens 610 may be integrated into a monolithic package, and laser source 600c and collimating lens 616 may be integrated into a monolithic package. In further embodiments, a phosphorus filter is integrated into a monolithic package, which may transform blue-colored light incident thereon into white light.

Although the various components of light source 202 are shown as separate components, any number of the various components can be integrated into single packages. For example, the laser sources and optical elements, such as the diverging elements, beam expanders, mirrors, lens, filters, apertures, collimators, and prisms, can be integrated into a single monolithic package. For example, laser source 600a, diverging element 602, and collimating lens 604 may be integrated into a single monolithic package. Similarly, laser source 600b, diverging element 608 and collimating lens 610 may be integrated into a single monolithic package, and laser source 600c, diverging element 614 and collimating lens 616 may be integrated into a single monolithic package. Alternatively, the laser source 600a, diverging element 602, collimating lens 604, optical element 612, laser source 600b, diverging element 608, collimating lens 610, laser source 600c, diverging element 614, collimating lens 616, optical element 618, diverging element 620, and collimating lens 622 may be integrated into a single monolithic package. In certain embodiments, a phosphorus filter may further be integrated into the single monolithic package, which may transform blue-colored light incident thereon into white light. Alternatively, any combination of components that may be integrated into single packages may be employed. Integrating the components into integrated monolithic packages may, for example, improve laser optics for easier alignment, a more robust system, and may also improve beam quality.

FIGS. 3C and 3D show embodiments of light source 202 according to further embodiments of the present invention. Although light source 202 show in FIGS. 3C and 3D are similar to those described with respect to FIGS. 3A and 3B, as shown in FIGS. 3C and 3D, light source 202 show source 600a, initial diverging element 602 and collimating lens 604 in a monolithic package, source 600b, initial diverging element 608 and collimating lens 610 in a monolithic package, and source 600c, initial diverging element 614 and collimating lens 616 in a monolithic package. In certain embodiments, a phosphorus filter may further be integrated into the single monolithic package, which may transform blue-colored light incident thereon into white light. FIGS. 3D and 3E further show that the monolithic packages of sources 600a, 600b and 600c may be disposed proximate each other. This configuration, for example, enables light source 202 to use a single heat sink 627 to dissipate the heat generated by sources 600a, 600b, 600c. Specifically, this configuration can minimize the physical size of light source 202 by placing sources 600a, 600b and 600c close to each other and removing the need for multiple heat sinks. In certain embodiments, a phosphorus filter may be positioned in the path of one or more or all of sources 600a, 600b and 600c. The small size of the entire assembly can provide flexibility in the design, application and use of light source 202.

Additionally, as shown in FIGS. 3D and 3E, where laser sources 600a, 600b and 600c are arranged in a parallel arrangement, light source 202 may further include mirror 626 to redirect light from one or more sources 600a, 600b, and 600c. For example, as shown in FIGS. 3D and 3E, mirror 626 may redirect light produced by laser source 600a to optical element 612. In certain embodiments, it may redirect light product by laser source 600a to a phosphorus filter, for example, a phosphorus filter positioned at or in the vicinity of, or in place of, optical element 612. In certain embodiments, a phosphorus filter may be positioned at or in the vicinity of the mirror. According to certain exemplary embodiments, mirror 626 may be orientated at substantially a 45° angle, relative to the incident light beam, to redirect light from source 600a to optical element 612. Alternatively, based on the arrangement of sources 600a, 600b, and 600c, one or more mirrors can be employed at any angles to redirect light produced by sources 600a, 600b, and 600c.

As shown in FIG. 3E, diverging element 620, which is included in light source 202 shown in FIG. 3D, may not be necessary if the beam expansion performed by diverging element 602, 608, 614, and collimating lenses 604, 610, 616, is sufficient to achieve a final desired beam diameter.

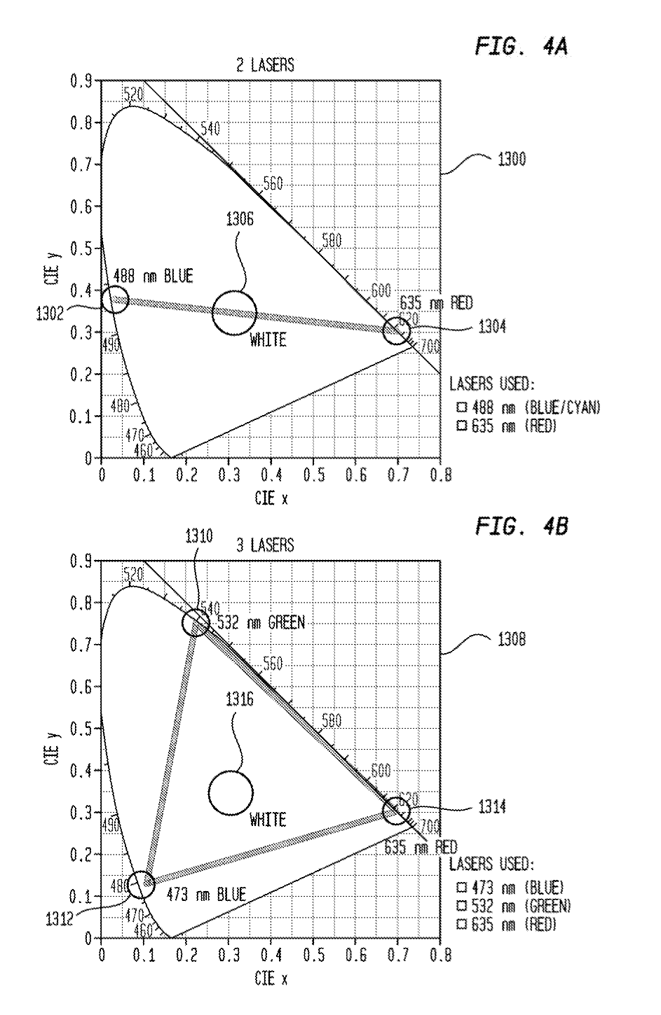

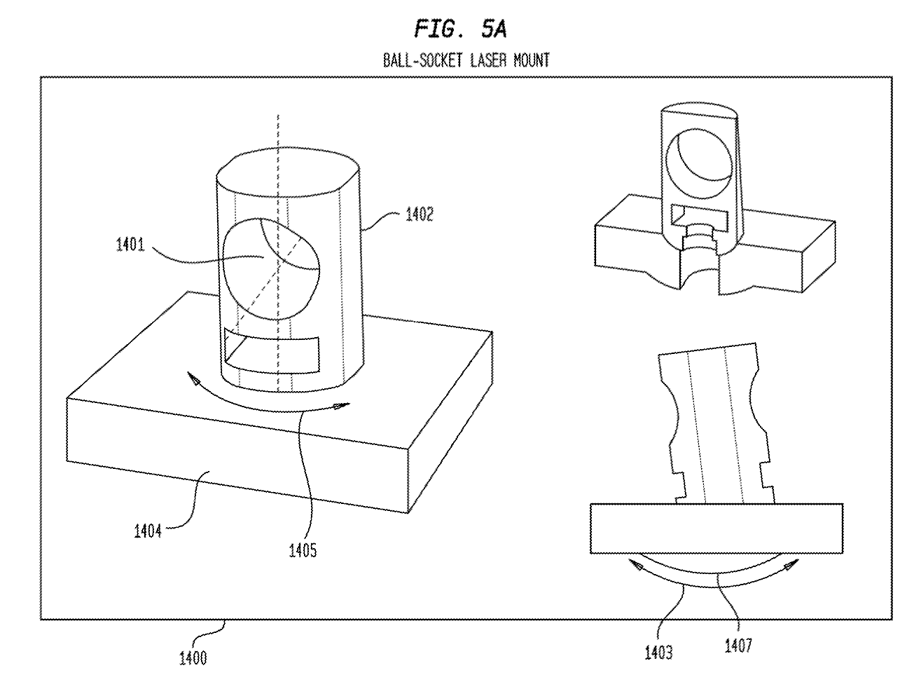

FIGS. 4A and 4B show color gamuts 1300 and 1308, showing how the wavelengths of light sources can be chosen to obtain a desired output light color. For example, a desired output light color can be chosen anywhere within color gamuts 1300 and 1308, and the number and types of sources can be selected and optimized in an effort to obtain the desired output light color. For example, as shown in FIGS. 4A and 4B, the desired color light is indicated by circles 1306 and 1316 shown in FIGS. 4A and 4B, respectively, and the range of colors achievable using the selected light sources is indicated with black circles. For example, as shown in FIG. 4A, where two light sources are used, the possible obtainable colors form a line (made up of black circles) running from indicated region 1304 to indicated region 1302. In FIG. 4B, where three light sources are used, the available colors all lie inside the triangle formed by indicated regions 1310, 1312, and 1314. In general, a geometric shape defined by the number of light sources used, where the wavelength emitted by each light source form the corners of the geometric shape (such as indicated by regions defined by vertices 1302, 1304, 1310, 1312, and 1314) may be overlaid on the color gamuts to indicate the range of achievable colors. After the desired color light and the number of sources have been determined, the appropriate geometry can be drawn onto the color gamut to represent the colors possible for the output light with the given sources. For example, the line in FIG. 4A shows how a desired color of white light 1306 can be produced by a combination of two sources 1302 and 1304 having wavelengths of approximately 488 nm and 635 nm, respectively. The relative intensities of two sources 1302 and 1304 may be adjusted to output light of any color along the line. As shown in FIG. 4B, the combination of three light sources 1310, 1312, 1314 can produce any of the colors within the area of the drawn triangle, including desired light 1316. The area of the triangle in FIG. 4B represents the possible wavelengths of output light that can be obtained by varying the relative intensities of sources 1310, 1312 and 1314. Specifically, FIG. 4B shows how a desired output light of white light may be produced by a combination of an approximately 473 nm blue light, an approximately 532 nm green light, and an approximately 635 nm red light. In certain embodiments, blue-colored light may be selected. In further embodiments, the blue-colored light passes through a phosphorus filter thereby creating a white light.

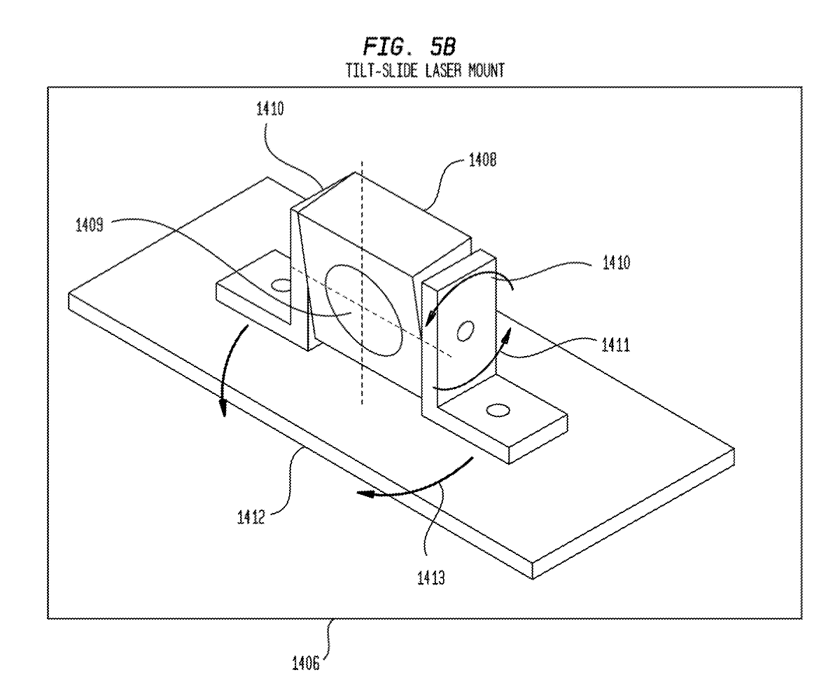

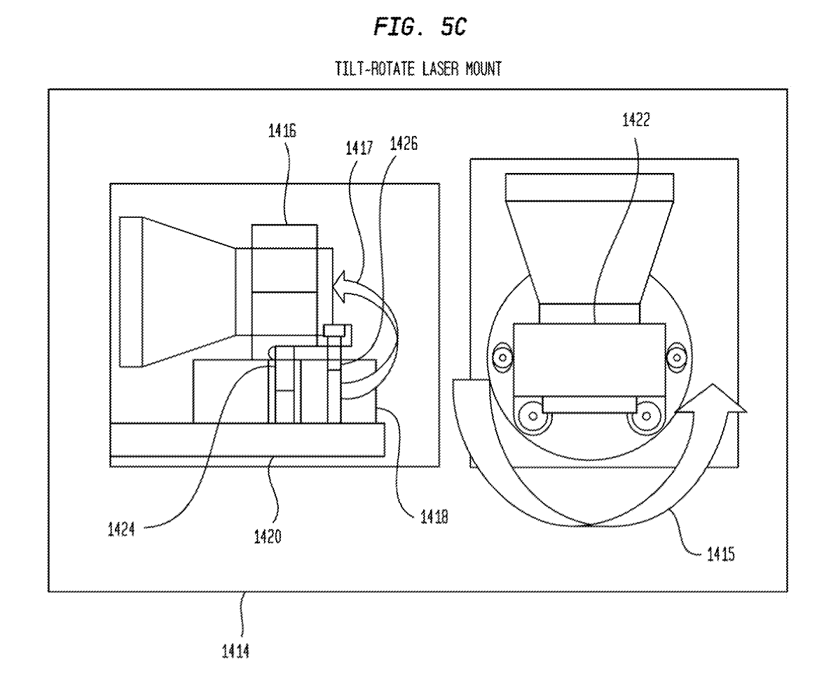

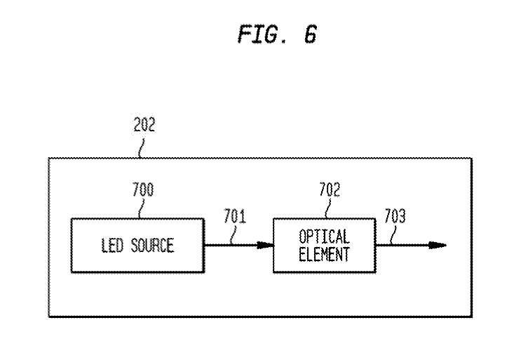

Translation stages and mounts may be used to be able to mount and adjust sources used in illuminating/lighting apparatus 100 in order to provide some adjustability to the placement of the various light sources and optical elements, and ensure proper mounting and alignment. FIGS. 5A, 5B and 5C show various mounts 1400, 1406, 1414, that may optionally be used for mounting the light sources within illuminating/lighting apparatus 100. FIG. 5A shows a ball-socket mount 1400 which may be used to mount a light source. The ball-socket mount 1400 may include a cylindrical main body 1402 with a circular opening 1401 within which a light source may be mounted. Further, main body 1402 may be inserted into opening 1401 in a base 1404. The coupling of base 1404 to main body 1402 preferably allows main body 1402 to be adjusted relative to base 1404 in multiple degrees of freedom, as depicted by arrows 1405 and 1403. For example, the cylindrical main body may provide rotational adjustment relative to horizontal, and base 1404 may include a curved protruding lower portion 1407, providing angular adjustment relative to vertical.

FIG. 5B shows a tilt-slide mount 1406 which may be used to mount a light source. The tilt-slide laser mount 1406 may include a rectangular main body 1408, with a circular opening 1409 where a light source may be mounted. Main body 1408 may be coupled to a rectangular base 1412 by two brackets 1410. Circular opening 1409 of main body 1408 may run perpendicular to main body 1408. Two brackets 1410 may be coupled to the sides of main body 1408 attaching each side of main body 1408 to base 1412 allowing for adjustment of the pitch of a light source mounted therein, as depicted by arrows 1411. Additionally, mount 1406 can provide adjustment of the yaw rotation of a light source as depicted by arrows 1413 via a sliding mechanism. Although FIG. 5B shows main body 1408 being coupled to base 1412 by brackets 1410, main body 1408 may be coupled to base 1412 by fasteners, braces, supports or any other element capable of coupling main body 1408 to base 1412 and providing tilting adjustment of the source mounted therein.

FIG. 5C shows a tilt-rotate mount 1414 which may be used to mount a light source. The tilt-rotate mount 1414 may include a main body 1416 which includes a circular opening 1422 perpendicular to main body 1416 for placement of a light source. Main body 1416 may be coupled to a circular platform 1418, which may be coupled to a rectangular base 1420. Platform 1418 may rotate about base 1420 allowing for rotational movement of main body 1416 and light source mounted therein, as depicted by arrows 1415. In addition, main body 1416 may have two protrusions 1424 and 1426 which may be inserted into platform 1418. Two protrusions 1424 and 1426 may be at different heights on main body 1416 allowing for adjustment of the pitch position of main body 1416 as depicted by arrows 1417.

FIG. 6 is a block diagram of light source 202 according to yet another embodiment of the present invention. As shown in FIG. 6, light source 202 may include LED source 700 and optical element 702. Although FIG. 6 shows light source 202 having one LED source and one optical element, light source 202 may include any number of LED sources and optical elements depending on the desired characteristics of the light that is to be outputted by light source 202. For example, the color, wavelength, intensity, brightness, power, shape, pattern, etc. of the light produced by illuminating/lighting apparatus 100 may be manipulated and adjusted using various designs and configurations of various components of light source 202. In certain embodiments, the light source or one or more or all of the number of LED sources may produce a blue-colored light. In further embodiments, this blue-colored light passes through a phosphorus filter, which may be positioned, for example, at or in the vicinity of, or in place of, the light source, the number of LED sources, or the optical element.

As shown in FIG. 6, light source 202 may include LED source 700 which produces light 701. Light 701 produced by LED source 700 may be conditioned, manipulated, and combined by optical element 702 to generate light 703 output by light source 202. For example, optical element 702 may narrow and collimate light 701 from LED source 700 to produce output light 703. In certain embodiments, the produced or outputted light may be blue-colored light, which, in further embodiments, may pass through a phosphorus filter.

According to one exemplary embodiment, LED source 700 may be an array of LEDs which generate light 701. Preferably, LED source 700 may include an array of white LEDs. In other embodiments, LED source 700 may include an array of LEDs producing a blue-colored light. In operation, optical element 702 may narrow and collimate light 701 generated by LED source 700 generating light 703, allowing light source 202 to output a collimated beam of light. According to certain exemplary embodiments, optical element 702 may include a collimating lens. In an exemplary embodiment where optical element 702 includes a collimating lens, optical element 702 may narrow and collimate light 701 generated by LED source 700. Optical element 702 may output light 703 which may then exit light source 202. Alternatively, optical element 702 may be a “flashlight”-like collector, a mirror, a Fresnel lens, a total internal reflection “light pipe” or any other type of optical element capable of manipulating and adjusting light beams appropriately or a combination thereof. In further embodiments, blue-colored light passes through a phosphorus filter, which may, for example, be positioned at or in the vicinity of the LED source 700, optical element 702, collimating lens, “flashlight”-like collector, mirror, Fresnel lens, total internal reflection “light pipe” or other light-manipulating adjusting optical element.

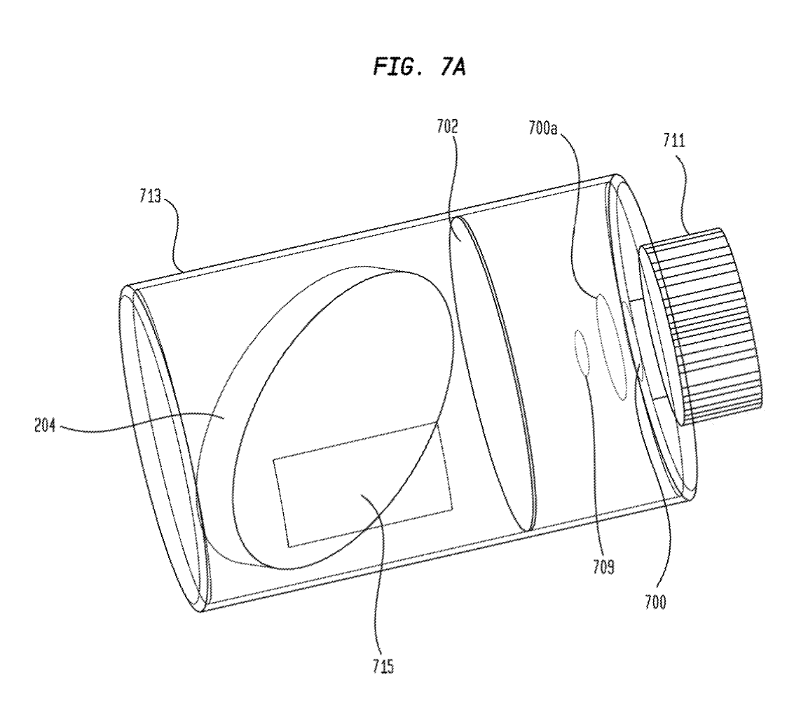

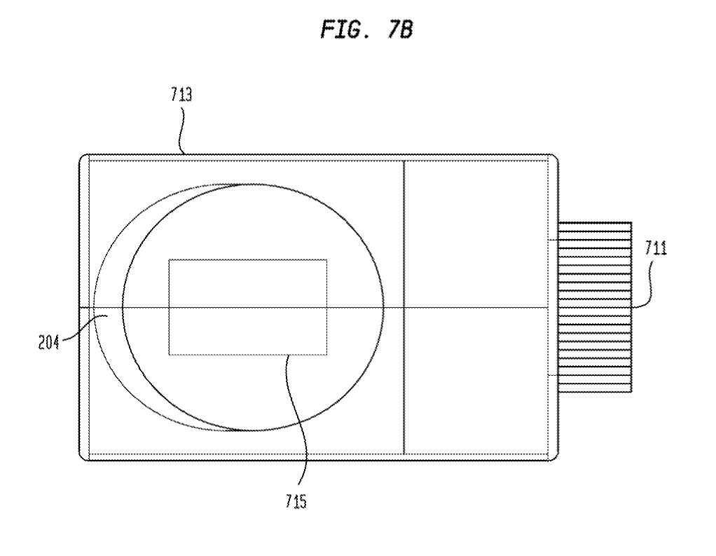

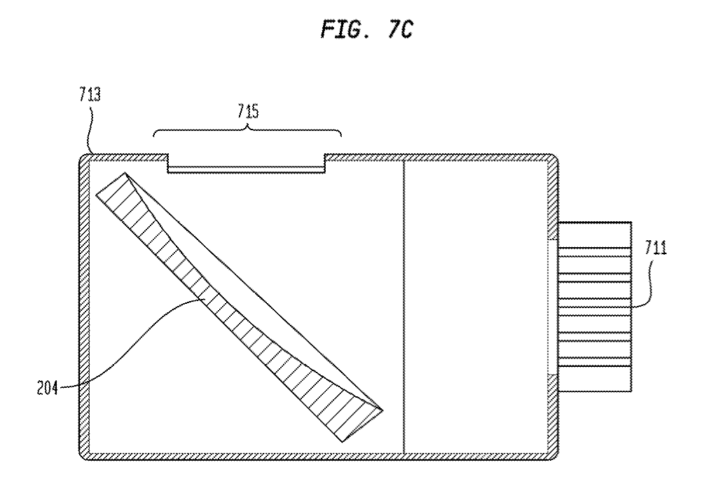

FIGS. 7A, 7B and 7C show a rendering of an illuminating/lighting apparatus according to an exemplary embodiment of the present invention, in which an LED light source 700 can be used. As shown in FIGS. 7A, 7B, and 7C, exemplary device 713 may include LED source 700, optical element 702, aperture plate 709, light dispersing element 204, window 715, and heat sink 711. In FIG. 7A the LED 700 source is depicted in an exploded view to enable viewing of LED mounting bracket 700a. LED source 700 may be any LED light source capable of producing a light with any desired characteristics. In certain embodiments, it may produce a blue-colored light. Aperture plate 709 may include, for example, a perforated opaque screen, and may create an array of effective light sources from the light produced by LED source 700. Optical element 702 may include, for example, a Fresnel lens, and may collimate light incident on it, after which the light would be incident on light dispersing element 204. As described herein, light dispersing element 204 may include a faceted parabolic reflector. For example, LED source 700 may generate a light, which may be incident on aperture plate 709, which creates an array of effective light sources. This light may then be collimated by optical element 702, which is then incident on light dispersing element 204. Light dispersing element 204 may then reflect the light, which may converge at the focal point of light dispersing element 204, through window 715. Heat sink 711 may be in contact with LED source 700, and may include a plurality of fins to facilitate cooling of LED source 700. In an alternative embodiment, aperture plate 709 may include a pin-hole aperture that may be used to collimate and narrow poorly collimated light produced by LED source 700. For example, light from LED source 700 may be incident on aperture plate 709, where aperture plate 709 may include a pin-hole aperture which may collimate and narrow light from LED source 700. Light from aperture plate 709 may then be further collimated by optical element 702, and then incident on light dispersing element 204. In further embodiments, a blue-colored light may pass through a phosphorus filter, thereby creating a white light, which phosphorus filter may, for example, be positioned at or in the vicinity of the aperture plate, the perforated opaque screen, the optical element, the Fresnel lens, the light dispersing element, the faceted parabolic reflector, or the window.

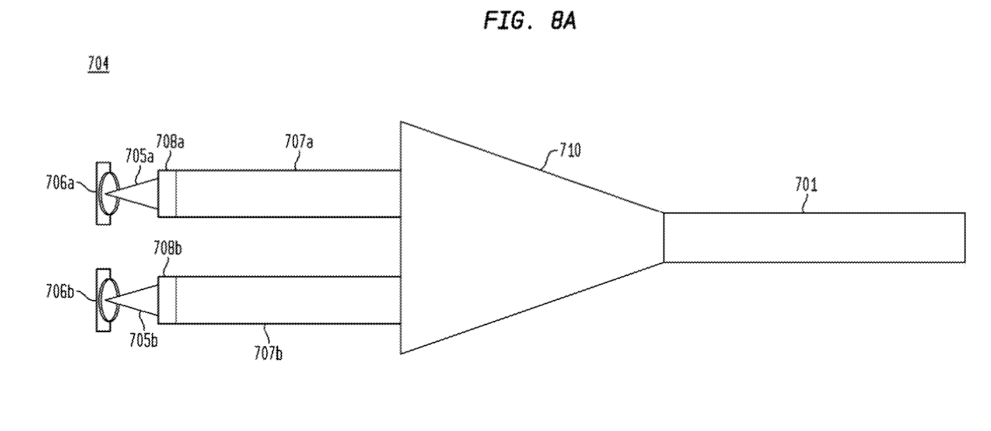

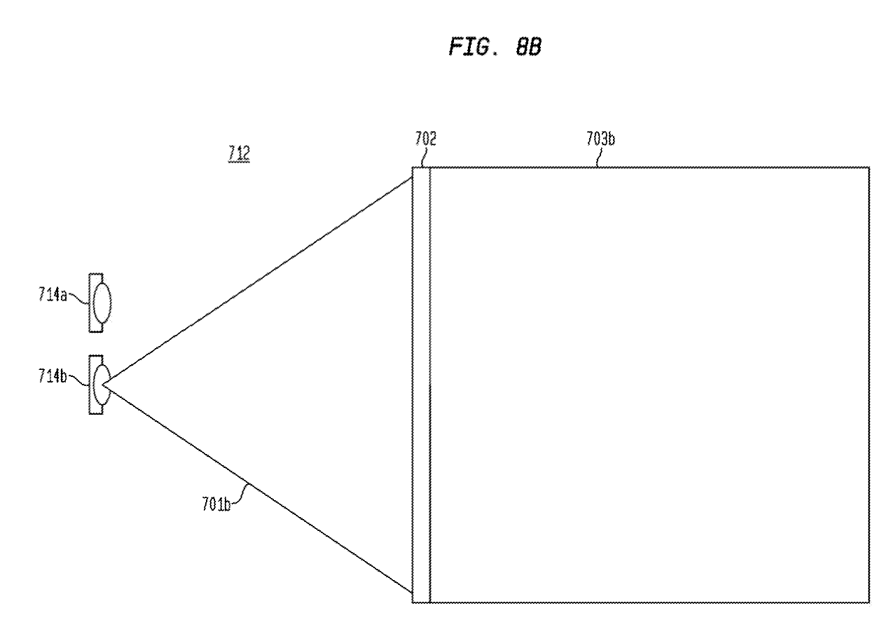

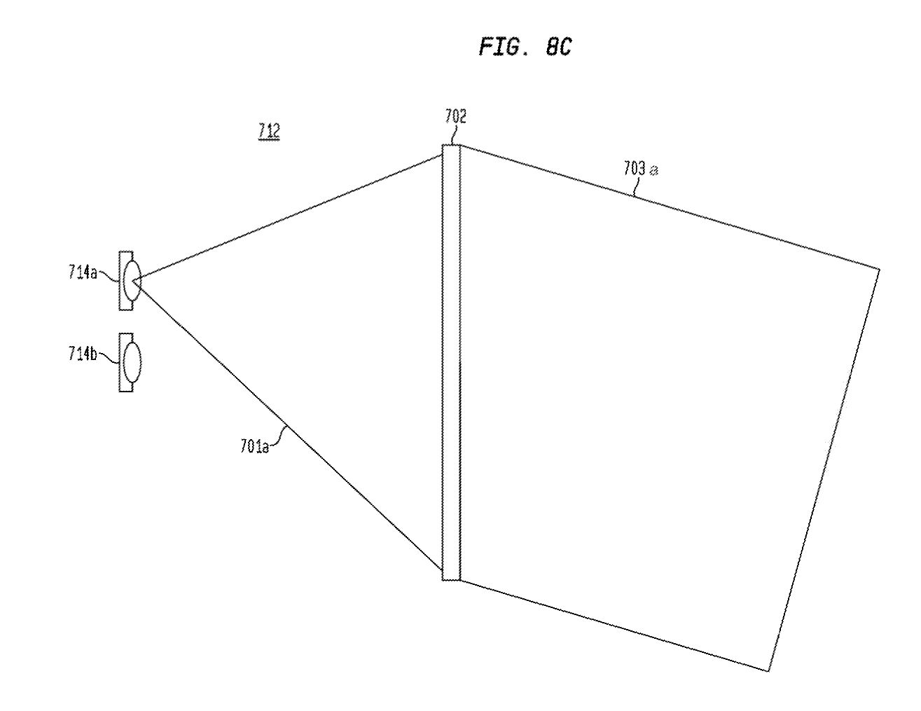

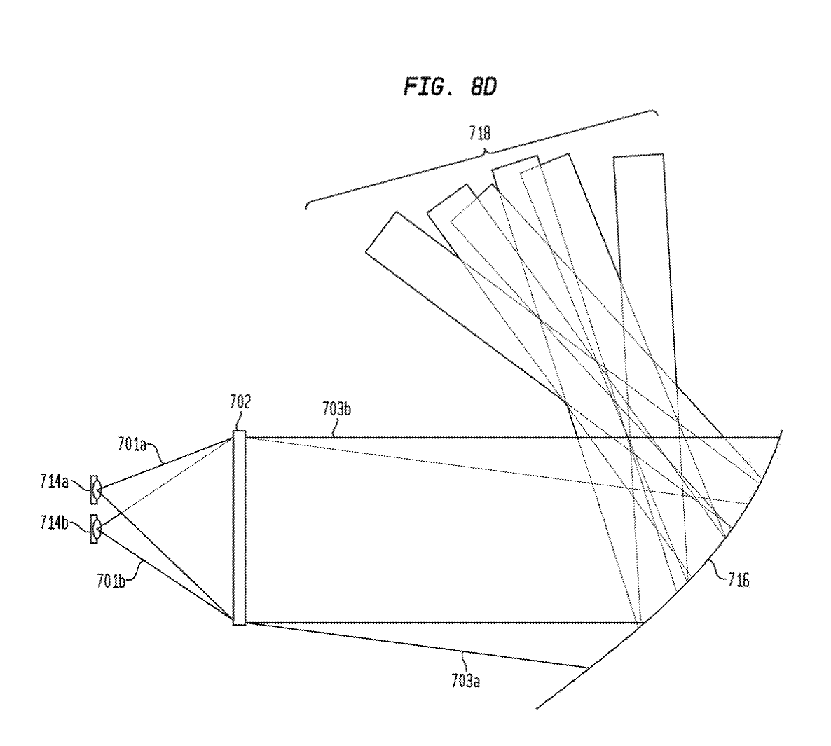

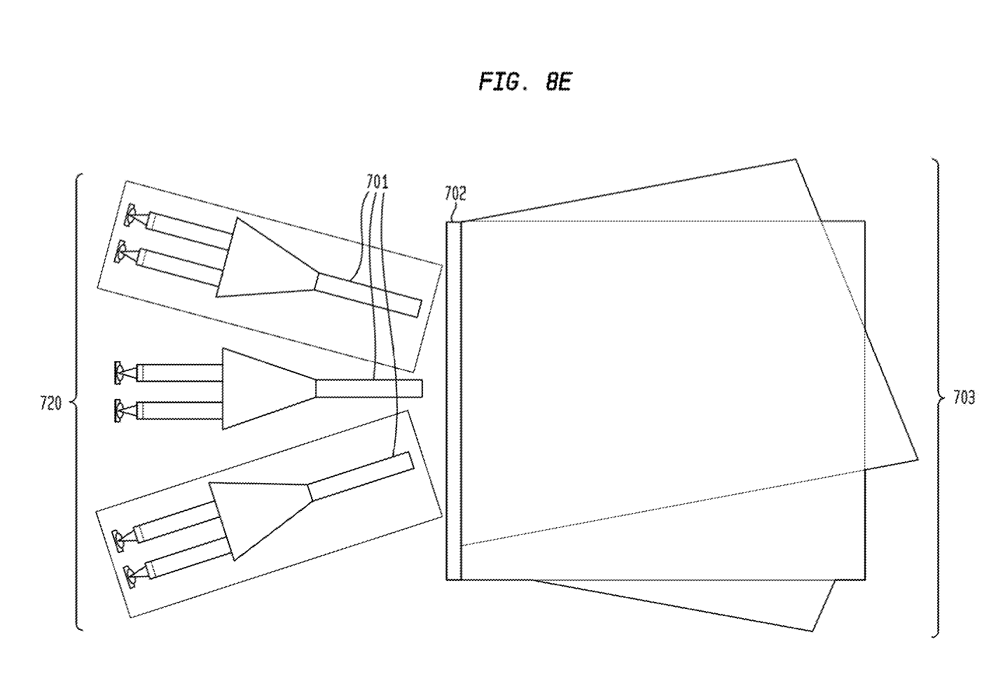

As shown in FIG. 8A, LED source 700 may include a light pipe assembly 704 to enable combining of multiple LEDs to obtain a brighter/higher intensity light. Although FIG. 8A shows light pipe assembly 704 having two LEDs 706a and 706b, light pipe assembly 704 may include only one LED, three LEDs, four LEDs or any number of LEDs. Preferably, LEDs 706a and 706b may include white LEDs. However, LEDs 706a and 706b may generate any desired colored light, and may each emit different wavelengths from the other. In certain embodiments, LED source 700 or one or more or all of the LEDs may generate a blue-colored light. In one embodiment of the present invention, light 705a and 705b generated by LED 706a and 706b may strike collimating lens 708a and 708b, narrowing and collimating light 705a and 705b, and outputting light 707a and 707b. Collimating lens 708a and 708b can include any such element that can narrow the light appropriately, and can include, for example, a mirror, lens or aperture or any other optical element capable of collimating light. Light 707a and 707b exiting collimating lens 708a and 708b may be incident on waveguide combiner 710, which may combine light 707a and 707b and output light 701. Light 701 may have an intensity that is greater than either light 707a or 707b entering waveguide combiner 710. Although FIG. 8A shows waveguide combiner 710 being used to combine two lights 707a and 707b produced by source 706a and 706b, the light of any number of sources may be combined using waveguide combiner 710. For example, lights of three, four, or five sources may be combined using waveguide combiner 710. In further embodiments, blue-colored light may pass through a phosphorus filter to create a white light, which phosphorus filter may, for example, be positioned at or in the vicinity of the LED source, the LEDs, the collimating lens, the mirror, the aperture, or other light collimating optical element, or the waveguide combiner.

Alternatively, as shown in FIGS. 8B and 8C, LED source 700 may include an off-set LED assembly 712 which generates light 701a and 701b. Although FIGS. 8B and 8C show off-set LED assembly 712 having two LEDs 714a and 714b, off-set LED assembly 712 may include, three LEDs, four LEDs or any number of LEDs desired. LEDs in the off-set LED assembly may be configured in any arrangement, including a 2D array of any size, and said array may be configured with any topology desired. Preferably, LEDs 714a and 714b may include LEDs generating a white light. Alternatively, LEDs 714a and 714b may generate any colored light desired, including configurations in which each LED emits a different color. In certain embodiments, LED source 700 or one or more or all of the LEDs may generate a blue-colored light. In one embodiment shown in FIG. 8B, light 701b generated by LED 714b may be incident on optical element 702, where optical element 702 may be a collimating lens. In an exemplary embodiment where optical element 702 includes a collimating lens, optical element 702 may narrow and collimate light 701b generated by LED 714b. Optical element 702 may narrow and collimate light 701b, outputting light 703b. FIG. 8C shows light 701a generated by LED 714a may strike optical element 702 at an angle off-set from the optical axis of optical element 702, where optical element 702 may be a collimating lens. In an exemplary embodiment where optical element 702 includes a collimating lens, optical element 702 may narrow and collimate light 701a generated by LED 714a. Optical element 702 may narrow and collimate light 701a, outputting light 703a at an angle off-set from the optical axis of optical element 702. Alternatively, optical element 702 may be a “flashlight”-like collector, mirror, lens, Fresnel lens, total internal reflection “light pipe” or any other type of optical element capable of manipulating and adjusting light beams. In further embodiments, blue-colored light may pass through a phosphorus filter to create a white light, which phosphorus filter may, for example, be positioned at or in the vicinity of the LED source, the LED assembly, the LEDs, the optical element, the collimating lens, the “flashlight”-like collector, the mirror, the lens, the Fresnel lens, or the total internal reflection “light pipe” or other light beam manipulating and adjusting optical element.

As shown in FIG. 8D, light 701a and 701b generated by LED 714a and 714b may be incident on optical element 702 at angles off-set from the optical axis of optical element 702. Light 703a and 703b may be off-set from each other and may be incident on optical element 702 at different angles of incidence. LEDs 714a and 714b may be positioned in the focal plane of optical element 702, near the optical axis, so that light 701a and 701b enters optical element 702 at an angle off-set from the optical axis of optical element 702 and optical element 702 emits light 703a and 703b. The angle that light 703a and 703b exits optical element 702 may be dependent on the displacement of LEDs 714a and 714b from the optical axis of optical element 702 resulting in light 703a and 703b being emitted from optical element 702 at different angles. Light 703a and 703b may be incident on light dispersing element 716 at various angles, generating multiple split beams of light 718, and may exit illuminating/lighting apparatus 100 and may strike a target surface creating distinct points of light. The number of distinct and discrete points of light produced on a target surface may be equal to the product of the number of LEDs in LED source 700 and the number of facets of the light dispersing element 716. In certain embodiments, blue-colored light may pass through a phosphorus filter which positioned at or in the vicinity of the light dispersing element or its facets.

Optionally, where brighter/higher intensity light sources are desired, each of LEDs 714a and 714b can be replaced by an LED light pipe assembly similar to the assembly shown in FIG. 8A. FIG. 8E shows one exemplary embodiment of the present invention, where LED source 700 may include an array of light pipe assemblies 720, where the output light of each of the light pipe assemblies is disposed in an offset arrangement as shown in FIGS. 8B and 8C. The operation of the configuration shown in FIG. 8E is substantially similar to those shown in FIGS. 8C and 8D, with the light produced by each LED source 714a and 714b being replaced by each the light output by each light pipe assembly 720. Accordingly, light 701 may be incident on optical element 702 at angles off-set from the optical axis of optical element 702, where optical element 702 may be a collimating lens. Optical element 702 may output light 703, where light 703 may be multiple beams of light at angles off-set from the optical axis of optical element 702. Alternatively, optical element 702 may be a “flashlight”-like collector, mirror, lens, Fresnel lens, total internal reflection “light pipe” or any other type of optical element capable of manipulating and adjusting light beams.

Each light pipe assembly in the array of light pipe assemblies of LED source 700 may be positioned in the focal plane of optical element 702, near the optical axis, so that optical element 702 emits light 703, which is collimated light from LED source 700. Light 703 exiting optical element 702 may be multiple beams of light, off-set from the optical axis of optical element 702. The angles that light 703 exits optical element 702 may be dependent on the arrangement of LED light pipe assemblies 720 from the optical axis of optical element 702 resulting in light 703 being emitted from optical element 702 at various angles off-set from the optical axis of optical element 702. Light 703 may exit light source 202 and strike light dispersing element 204 at various off-set angles generating multiple distinct spots of light.

Further embodiments of the present invention contemplate utilizing other light sources, which, in yet further embodiments, generate blue-colored light which ultimately travels through a phosphorus filter to transform into white light. According to yet another embodiment of the present invention, light source 202 may include an array of fiber optic cables. The array of fiber optic cables may be integrated into a monolithic package with collimating lenses. The phosphorus filter may also be integrated into the monolithic package, for example, at or in the vicinity of the fiber optic cables or the collimating lenses. In one embodiment of the present invention, light source 202 may include different color lasers which are combined to create a specific color of light. For example, light source 202 may include a nanoscale semiconductor capable of generating red, green and blue lasers that are combined to create a white light. The nanoscale semiconductor laser may be integrated into a monolithic package. Using a nanoscale semiconductor laser eliminates the need for multiple laser sources. The nanoscale semiconductor is able to output a beam of white light without the use of multiple laser sources and optical elements. The beam of white light outputted by the nanoscale semiconductor may directly enter light dispersing element 204. Alternatively, light source 202 may include a supercontinuum laser, a frequency comb, a faceted 3D surface including a plurality of light emitting regions (e.g., a plurality of organic LEDs (OLEDs) on each facet and each individually electrically addressable), combination of red, green, and blue emitters into a single monolithic waveguide combiner, and the like. In certain embodiments where blue-colored light is generated by the light sources, the phosphorus filter may be positioned, for example, at or in the vicinity of the nanoscale semiconductor, the light dispersing element, the supercontinuum laser, the frequency comb, the faceted 3D surface, or the waveguide combiner.

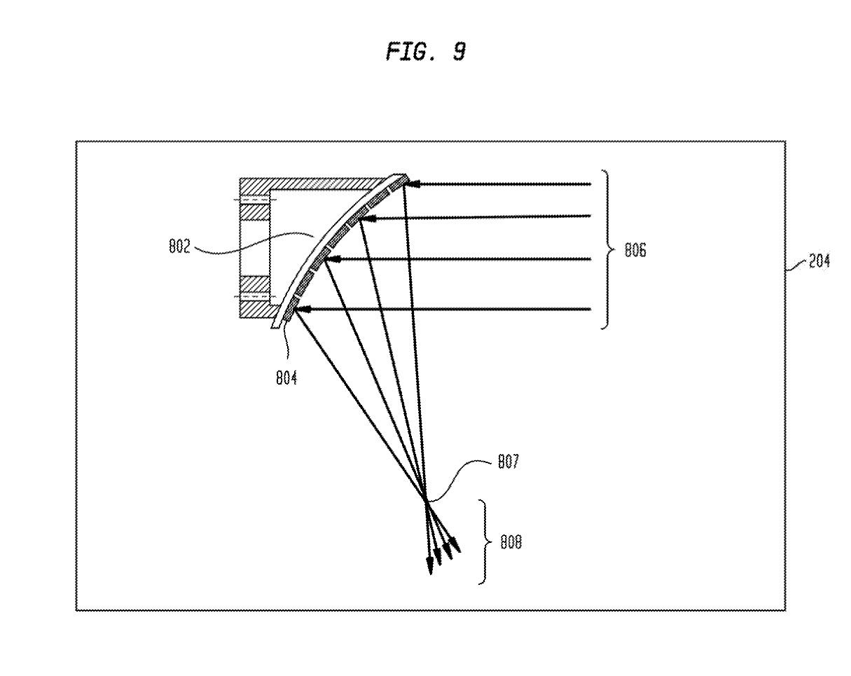

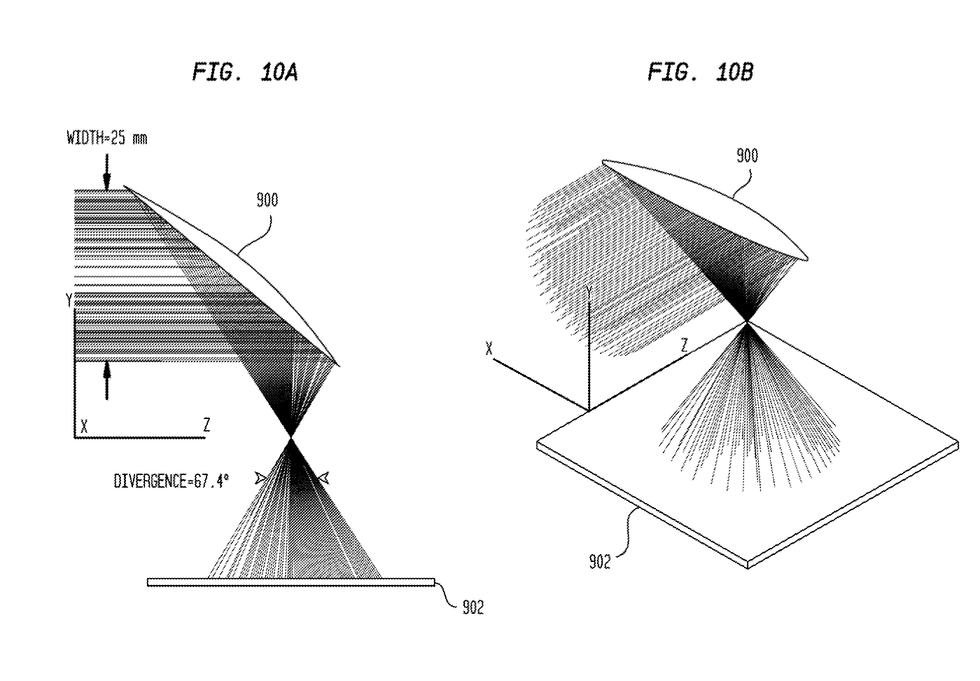

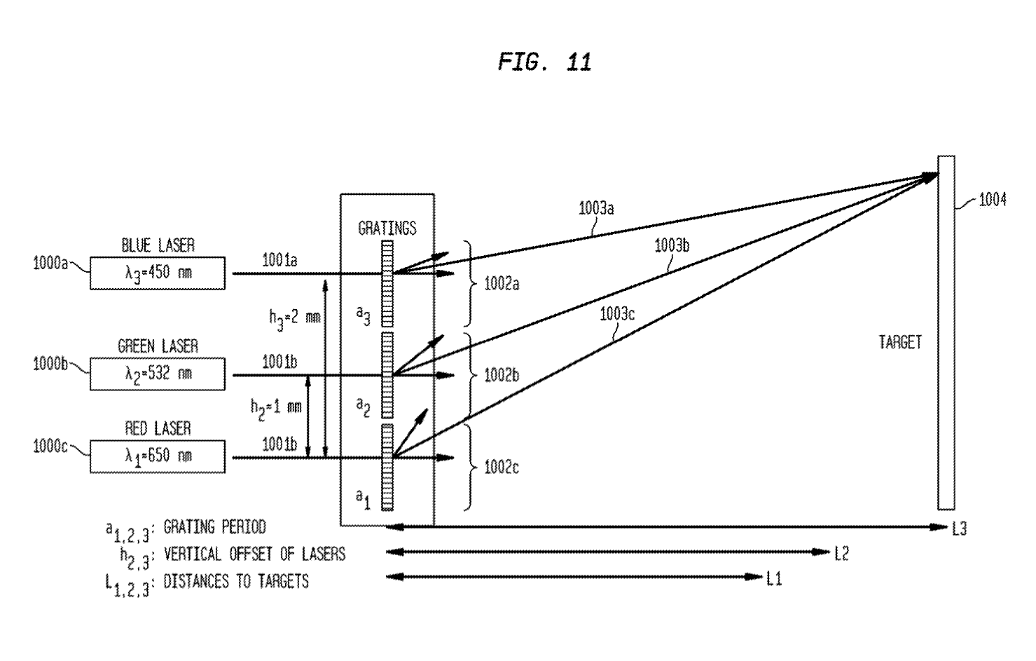

FIG. 9 shows an exemplary light dispersing element 204 according to certain exemplary embodiments of the present invention. Within illuminating/lighting apparatus 100, light dispersing element 204 receive light from source 202 (which, in certain embodiments, may produce a blue-colored light) and creates discrete points of light to be projected onto a target surface. As shown in FIG. 9, light dispersing element 204 may include a mirror 802 capable of reflecting light 806 received from a light source, such as light source 202, through aperture 206 of illuminating/lighting apparatus 100. Specifically, FIG. 9 shows a cut-away portion where light dispersing element 204 may be off-axis parabolic (OAP) multi-faceted mirror 802. In one embodiment of the present invention, light 806, such as light generated by light source 202, may strike OAP multi-faceted mirror 802 at an angle of incidence that is off-axis from the parabola orientation. The parabolic, concave shape of OAP multi-faceted mirror 802 may reflect incident light 806 while creating light 808 to split and emerge from aperture 206 of illuminating/lighting apparatus 100. Preferably, the diameter of the light beam received by OAP multi-faceted mirror 802 is equal to or greater than the diameter of the OAP multi-faceted mirror 802 that is presented to the incident beam so as to ensure that the surface of OAP multi-faceted mirror 802 is completely covered in light. This can be accomplished, for example, by ensuring that diverging elements 406, 504, 620 and collimating lenses 408, 506, 622 expand the diameter of light produced by light source 202 sufficiently. As shown in FIG. 10, the shape of OAP multi-faceted mirror 802 may be parabolic and concave resulting in the split light 808 converging to focal point 807 of OAP multi-faceted mirror 802. Preferably, as shown by 808, the light may then diverge as it travels to the target surface. Preferably, the split light passes through aperture 206 of illuminating/lighting apparatus 100 at focal point 807 of the parabolic mirror 802 before diverging as it travels to a target surface. In certain embodiments, blue-colored light passes through a phosphorus filter to create a white light, which phosphorus filter may, for example, be positioned at or in the vicinity of, the source, the light dispersing element, the mirror, the aperture, the OAP multi-faceted or parabolic mirror, the diverging elements, the collimating lenses, or the focal point.

According to one embodiment of the present invention, OAP multi-faceted mirror 802 may be comprised of a plurality of discrete facets 804 (at or in the vicinity of which, in certain embodiments, a phosphorus filter may be positioned). Collimated light 806 emitted from collimating lens 408, 506, 622 may strike facets 804, and each of facets 804 may reflect a small portion of the collimated light 806 into discrete beams of light 808. Distinct smaller beams of light 808 may exit illuminating/lighting apparatus 100 through aperture 206. Aperture 206 may be located at focal point 807 of OAP multi-faceted mirror 802. Additionally, aperture 206 may act as a “biscuit cutter,” cutting off the edges of the light passing there-through, thereby limiting the divergence of beams of light 808 and reducing the angular spread of the discrete beams of light emitted from aperture 206 by blocking beams with the largest angle relative to the optical axis.

In one embodiment of the present invention, OAP multi-faceted mirror 802 may include an array of facets separated by flexible joints, with a metallic coating applied to the facets and the array of facets formed into a parabolic bowl. Preferably, OAP multi-faceted mirror 802 may be an array of flat facets with a reflective surface, separated by flexible joints and formed to a parabolic bowl. Preferably, the facet placements may be controlled. Exemplary embodiments of the array of facets may be an array of circles or squares having the dimensions of 3.5 mm×3.5 mm, 2 mm×2 mm, 1 mm×1 mm or 0.5 mm×0.5 mm. However, the array of facets may be an array of any shape, any pattern and of any size capable of receiving incoming light and separating the incident light into distinct and discrete points of light on a target surface. In one embodiment of the present invention, an array of approximately 100 11 mm×11 mm facets can produce approximately 1,000 distinct and discrete points of light on a target surface.

FIGS. 10A and 10B show computer simulations depicting light striking an OAP multi-faceted mirror 900 and being reflected on a target surface 902. As shown in FIG. 10A, OAP multi-faceted mirror 900 may receive an approximately 25 millimeter diameter collimated beam along the z-axis and reflects the collimated beam 90° in the z-y plane and creating a divergence angle of approximately 67.4°. In one embodiment of the present invention, the curvature of OAP multi-faceted mirror 900 can include a surface described by the following equation:

$$z = \frac{{x}^{2} + {y}^{2}}{4 f}$$

In one embodiment of the present invention, f=9.3750 mm, x ranges from 10.0347 mm to 35.0347 mm and y ranges from −12.5 mm to 12.5 mm. Preferably, a circular cross-section may be presented to the incoming beam by further restricting x and y pairs that satisfy the following equation (x+22.5347)²+y²=12.5². In another embodiment of the present invention, f=38.1 mm, x ranges from 40.781 mm to 142.381 mm and y ranges from −50.8 mm to 50.8 mm. Preferably, a circular cross-section may be presented to the incoming beam by further restricting x and y pairs that satisfy the following equation (x+91.581)²+y^{Z}=50.82. In general, the selection of x and y may be restricted to satisfy the following equation (x−x̅)²+y²≦r², where x̅ is the mean of the range of x values and r is the radius of the projected circle. In one embodiment of the present invention using a laser source, x̅=22.5347 mm and r=12.5 mm. In another embodiment of the present invention using an LED source, x̅=91.581 mm and r=50.8 mm.

In another embodiment of the present invention, light dispersing element 204 may include a smooth curved parabolic mirror (at or in the vicinity of which, in certain embodiments, a phosphorus filter may be positioned). The light emerging from the smooth curved parabolic mirror may be a single beam of light opposed to the split beams of light. According to another embodiment of the present invention, light dispersing element 204 may include one or more non-parabolic mirror, curved mirror, or flat mirror capable of reflecting light and producing discrete points of light on a surface approximately 10 mm (0.4 inches) on a target 15.2 meters (50 feet) away. In further embodiments, a phosphorus filter may be positioned at or in the vicinity of the non-parabolic mirror, curved mirror, or flat mirror. The shape, size, pattern, reflectivity and configuration of light dispersing element 204 may be modified to obtain any desired shape, design, pattern, size, brightness, intensity, power and/or configuration of the output light to be projected from illuminating/lighting apparatus 100 onto the target surface.

According to one embodiment of the present invention, OAP multi-faceted mirror 802 may be manufactured with molded plastic and reflective coating wherein the plastic parabolic faceted bowl may be made via injection molding and then reflective coated. Alternatively, OAP multi-faceted mirror 802 may be manufactured by applying reflective particles to a parabolic bowl. In one embodiment of the present intention, OAP multi-faceted mirror 802 may be manufactured with molded plastic and embossed or stamped reflective layer wherein the plastic parabolic faceted bowl may be made by via injection molding, then reflective film or sheet metal may be stamped into the plastic parabolic faceted bowl. In yet another embodiment of the present intention, OAP multi-faceted mirror 802 may be manufactured with an unfaceted molded plastic bowl with a laser-etched faceted reflective sheet wherein the plastic parabolic bowl may not contain facets. A layer of some thickness with a reflective surface may be etched with the facet geometry and may be laid into the plastic molded bowl. In one embodiment of the present intention, OAP multi-faceted mirror 802 may also be manufactured with a stamped reflective faceted metal bowl wherein the facet geometry may be stamped into the metal plate with a mold. In another embodiment of the present intention, multi-faceted mirror 802 may be manufactured by manually placing reflective squares or reflective glitter into a plastic parabolic bowl. In one embodiment of the present invention, OAP multi-faceted mirror 802 may be manufactured by generating wax castings of a parabolic bowl from a CNC die and applying a metallic coating to the parabolic bowl. In one embodiment of the present invention, OAP multi-faceted mirror 802 may be manufactured by using a die to press metal into a faceted parabolic shape. Alternatively, OAP multi-faceted mirror 802 may be manufactured using rapid prototyping, 3D printing, etching, die casting, molding, forging, pressing, bending, machining or any other manufacturing method capable of creating a multi-faceted mirror bowl.

In one embodiment of the present invention, the array of facets may be manufactured using lithography followed by etching. In one embodiment of the present invention, polydimethylsiloxane (PDMS) may be patterned and etched using well established commercial processes to create the array of facets. In one embodiment of the present invention, the array of facets may be manufactured using PDMS molding. PDMS may be poured into a mold and cured to create an array of facets. In one embodiment of the present invention, an array of facets be created using laser etching. Preferably, the array of facets has a target radius of flatness >5 millimeters with a target depth to width ratio of 10.

According to certain exemplary embodiments, OAP multi-faceted mirror 802 may be coupled to a motor assembly driving a movement of multi-faceted mirror 802. The movement may be programmable, and may be controlled by a controller. For example, multi-faceted mirror 802 may be rotated in a circular motion, moved linearly back and forth, rotated through an arc, etc. by the motor assembly. Movement of multi-faceted mirror 802 can allow, for example, the plurality of discrete points of light to move across the target surface in a desired pattern. For example, the movement of multi-faceted mirror 802 may cause the discrete points of light to rotate across the target surface, move horizontally, rotate in an arcing pattern, move vertically, move vertically downward to mimic falling stars or snow, etc. Optionally, the movement of OAP multi-faceted mirror 802 may be adjusted by a user. For example, a user may control the speed, direction, duration or other properties of the rotation of the OAP multi-faceted mirror 802. Alternatively, the use of a microelectromechanical system mirror array may be used to create motion effects of the discrete points of light.

FIG. 11 shows one embodiment of the present invention where light dispersing element 204 may include diffraction gratings (at or in the vicinity of which, in certain embodiments, a phosphorus filter may be positioned). Diffraction gratings may be used to split and diffract an incoming light and output multiple beams of light on a target surface. As shown in FIG. 11, sources 1000a, 1000b, 1000c may generate light (which, in certain embodiments, may be blue-colored light) that passes through diffraction gratings 1002a, 1002b, 1002c, respectively. Diffraction grating 1002a diffracts light 1001a at a given angle into multiple beams of light 1003a, diffraction grating 1002b diffracts light 1001b at a given angle, which may be the same or different than the angle at which diffraction gratings 1002a and 1002c diffract incoming light, into multiple beams of light 1003b, and diffraction grating 1002c diffracts light 1001c at a given angle, which may be the same or different than the angle at which diffraction gratings 1002a and 1002c diffract incoming light, into multiple beams of light 1003c. Each of the multiple beams of light 1003a, 1003b, 1003c strike target 1004 at particular points, which are dependent on the period of diffraction gratings 1002a, 1002b, 1002c and the wavelengths of light 1001a, 1001b, and 1001c, so that the lights 1001a, 1001b, and 1001c are combined at each particular point on target 1004, thereby combining at each particular point to create a different colored light. In an alternative embodiment, multiple diffraction gratings may be used for each source 1000a, 1000b, 1000c to combine multiple beams of light 1003a, 1003b, and 1003c into a combination beam of light.

In one embodiment, source 1000a generates a blue light, source 1000b generates a green light and source 1000a generates a red light. The diffraction gratings 1002a, 1002b, 1002c split the blue light, green light and red light respectively, creating split beams of blue, green and red light. The split beams of blue, green and red light combine at the particular points on target 1004 dependent on the period of diffraction gratings 1002a, 1002b, 1002c and the wavelength of light generated by laser sources 1000a, 1000b, 1000c, resulting in the combination of blue, green and red light at each particular point. The combination of blue, green and red light at each particular point may result in discrete points of white light to be created at each particular point.

In one embodiment of the present invention, diffraction gratings 1002a, 1002b, 1002c may be different for each respective wavelength of light to ensure proper overlapping and combination of red, green and blue light to create white light. The angle through which light is diffracted may be dependent on the wavelength and period of the grating. Insufficient overlap of the light on target 1004 may cause colored fringes.

In varying embodiments of the present invention, light source 202 may combine, manipulate, and condition beams of light in any manner desired to produce an output beam of light of the desired characteristics, including in certain embodiments, by producing blue-colored light and manipulating and/or conditioning it by passing it through a phosphorus filter to transform it into a white light. In one embodiment of the present invention, light source 202 may use 2D modulation of a beam of light with a spatial light modulator-liquid-crystal display (SLM-LCD) capable of varying the spatial transmission of a beam of light within a plane to change the desired characteristics of the light that is to be output by light source 202. The SLM-LCD may be used to shape the beam of light generated by sources of light source 202 to increase the overlap of the combination beam of light or to modulate the intensity of the output light of light source 202. In another embodiment of the present invention, parabolic or shaped reflectors may be used to combine the beams of light generated by sources. In yet another embodiment of the present invention, light source 202 may use mechanical means to combine light generated by the sources of light source 202. For example, the sources of light source 202 may be placed on a rotating substrate which may face light dispersing element 204, which may be an off-axis parabolic mirror. As the substrate rotates, the sources of light source 202 may move in a circle that cross the focal point of the off-axis parabolic mirror. In one embodiment of the present invention, the sources of light source 202 may be pulsed in a manner synchronized with the rotation of the off-axis parabolic mirror such that the sources are only pulsed when they are at the focal point of the off-axis parabolic mirror creating a pulsed collimated output beam of light which cycles through the colors of light generated by the sources. If the rotation frequency is high enough such that the duration of each color within the beam is shorter than the temporal resolution of the human visual system, the output beam of light will appear to be a combination of the light generated by the sources of light source 202. In an alternative embodiment of the present invention, a grating on an input of a fiber or waveguide may be used to combine light generated by the sources of light source 202. Each beam of light generated by the sources of light source 202 may be refracted by a different angle by the grating. By using different angles of incidence for the beams of light generated by the sources, the beams of light may be directed into a fiber or waveguide. In certain embodiments, a phosphorus filter may, for example, be positioned at or in the vicinity of the light source, the SLM-LCD, the parabolic or shaped reflectors, the light dispersing element, the off-axis parabolic mirror, the focal point of the off-axis parabolic mirror, or the grating.

According to certain embodiments of the present invention, illuminating/lighting apparatus 100 may include features that enable the user to customize the light being produced by illuminating/lighting apparatus 100. For example, illuminating/lighting apparatus 100 may include switches and dials that enable a user to, for example, change the color of the light produced by illuminating/lighting apparatus 100, including to a blue-colored light, change the shape of the discrete points of light projected onto a target surface by illuminating/lighting apparatus 100, activate a movement of the light across the target surface, change the brightness/intensity/power of the light by illuminating/lighting apparatus 100, position a phosphorus filter in the path of a blue-colored light so as to generate a white light, etc. In certain embodiments of the present invention where light source 202 includes laser sources, this may be accomplished, for example, by enabling the switches/dials to power on/off one or more of the laser sources or vary the brightness/intensity/power of any of the laser sources. Powering on/off any of the sources and/or varying the brightness/intensity/power can result in different combinations of lights resulting in a different color light that is output by illuminating/lighting apparatus 100. Additionally, shapes and movement of the light can be customized and changed by the user. For example, a user may control the speed, pattern, direction, duration or other properties of the movement of the light.

In one embodiment of the present invention, a distinct cut-out pattern may be placed in front of light source 202 (which light source 202 may, in certain embodiments, generate a blue-colored light). The pattern may allow the resulting light from light source 202 to have a distinct desired pattern. For example, light 203 from light source 202 may strike the distinct cut-out pattern prior to light 203 entering light dispersing element 204. However, the distinct cut-out pattern may be placed anywhere in the illuminating/lighting apparatus 100 such as after light dispersing element 204. As a result of the distinct cut-out pattern being placed prior to light dispersing element 204, light 203 emitted from light source 202 may be in the shape of the distinct cut-out pattern resulting in light 203 exiting light source 202 having a distinct desired pattern prior to striking light dispersing element 204. The light exiting illuminating/lighting apparatus 100 may have the distinct desired pattern resulting in spots of light having the distinct desired pattern on a target surface. The spots of light having the distinct desired pattern on the target surface may be any pattern that is determined by the distinct cut-out pattern allowing the spots of light on the target surface to vary in shape and size. Alternatively, a pattern may be cut into aperture plate 709 prior to the light striking light dispersing element 204 resulting in illuminating/lighting apparatus 100 projecting a distinct desired pattern on a target surface. The pattern may be cut, etched, engraved, or any other method capable of placing a pattern into an aperture plate. In certain embodiments, a phosphorus filter may be positioned at or in the vicinity of the cut-out patter, the light dispersing element, or the aperture plate and/or aperture thereof.

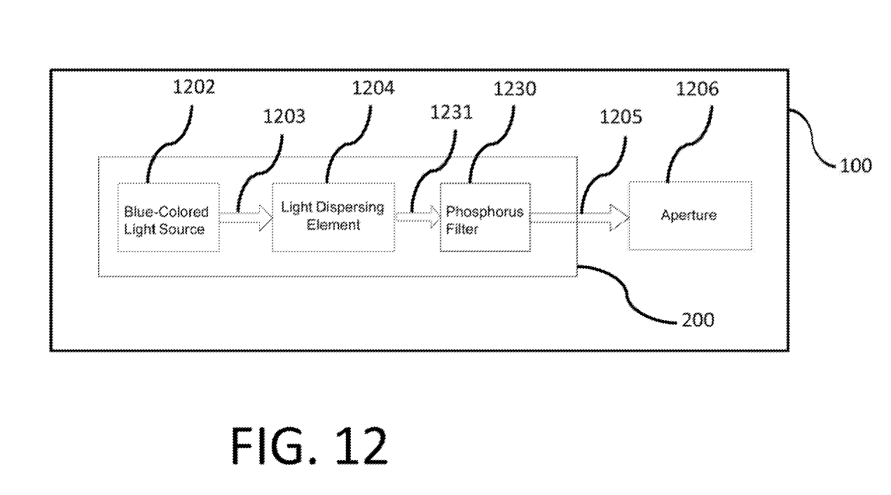

In accordance with embodiments of the present invention, FIG. 12 shows a block diagram representation of illuminating/lighting apparatus 100. As shown in FIG. 12, illuminating/lighting apparatus 100 may include a light assembly 200 and an aperture 1206. Light assembly 200 may include blue-colored light source 1202 (e.g., a blue laser) and light dispersing element 1204. As shown in FIG. 12, blue-colored light source 1202 may produce blue-colored light 1203 which is received and manipulated by light dispersing element 1204, which then outputs blue-colored light 1231, which in turn passes through phosphorus filter 1230, transforming the blue-colored light to white light 1205, which in turn passes through aperture 1206. In certain embodiments, the phosphorus filter may be positioned elsewhere in the path of the blue-colored light 1203, for example, at or in the vicinity of blue-colored light source 1202, light dispersing element 1204, and/or aperture 1206. Blue-colored light source 1202 may include any type of light source that is capable of producing the desired blue-colored light. For example, blue-colored light source 1202 may be designed so as to produce light having a certain wavelength or color of blue-colored light (for example, 450 nm, approximately 450 nm, 445 nm-455 nm, or a light with a blue appearance), a certain power or intensity, or certain angular divergence properties. According to certain exemplary embodiments, blue-colored light source 1202 may include one or more lasers, LED, LED lamps, halogen bulbs, high-intensity discharge gas lamps, fiber optic lighting systems, or any other mechanism capable of producing blue-colored light. Light dispersing element 1204 preferably receives light 1203 from blue-colored light source 1202 and manipulates and conditions the received light to a desired output light. According to certain exemplary embodiments of the present invention, light dispersing element 1204 receives light 1203 from blue-colored light source 1202 and creates a plurality of discrete points of light, which may be output (after passing through phosphorus filter 1230) by illuminating/lighting apparatus 100 through aperture 1206 onto a target surface. Light dispersing element 1204 may include any mechanism by which light 1203 produced by blue-colored light source 1202 may be dispersed and/or manipulated and projected out of illuminating/lighting apparatus 100. For example, light dispersing element 1204 may include a mirror, lens, reflector, diffraction grating, refractor, prism, charged-coupled device, microlens array, color wheel, or any other optical element capable of dispersing or manipulating light. In certain embodiments, the phosphorus filter may be positioned at or in the vicinity any of these components.

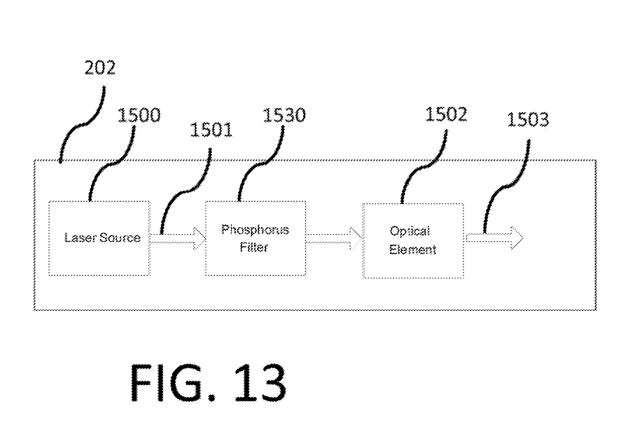

FIG. 13 is a block diagram of light source 202 according to yet another embodiment of the present invention. As shown in FIG. 13, light source 202 may include laser source 1500 (which may produce blue-colored light), phosphorus filter 1530, and optical element 1502. Although FIG. 13 shows light source 202 having one laser source, one phosphorus filter and one optical element, light source 202 may include any number of laser sources, phosphorus filters and optical elements depending on the desired characteristics of the light that is to be outputted by light source 202. For example, the color, wavelength, intensity, brightness, power, shape, pattern, etc. of the light produced by illuminating/lighting apparatus 100 may be manipulated and adjusted using various designs and configurations of various components of light source 202. In certain embodiments, the light source or one or more or all of the number of laser sources 1500 may produce a blue-colored light 1501. In further embodiments, this blue-colored light passes through a phosphorus filter 1530, which may be positioned, for example, at or in the vicinity of, the light source, the number of laser sources 1500, or the optical element 1502.

As shown in FIG. 13, light source 202 may include laser source 1500 which produces light blue-colored light 1501. Blue-colored light 1501 produced by laser source 1500 may be conditioned, manipulated, and combined by optical element 1502 to generate light 1503 output by light source 202. For example, phosphorus filter 1530 may transform the blue-colored light to white light to produce output light 1503.

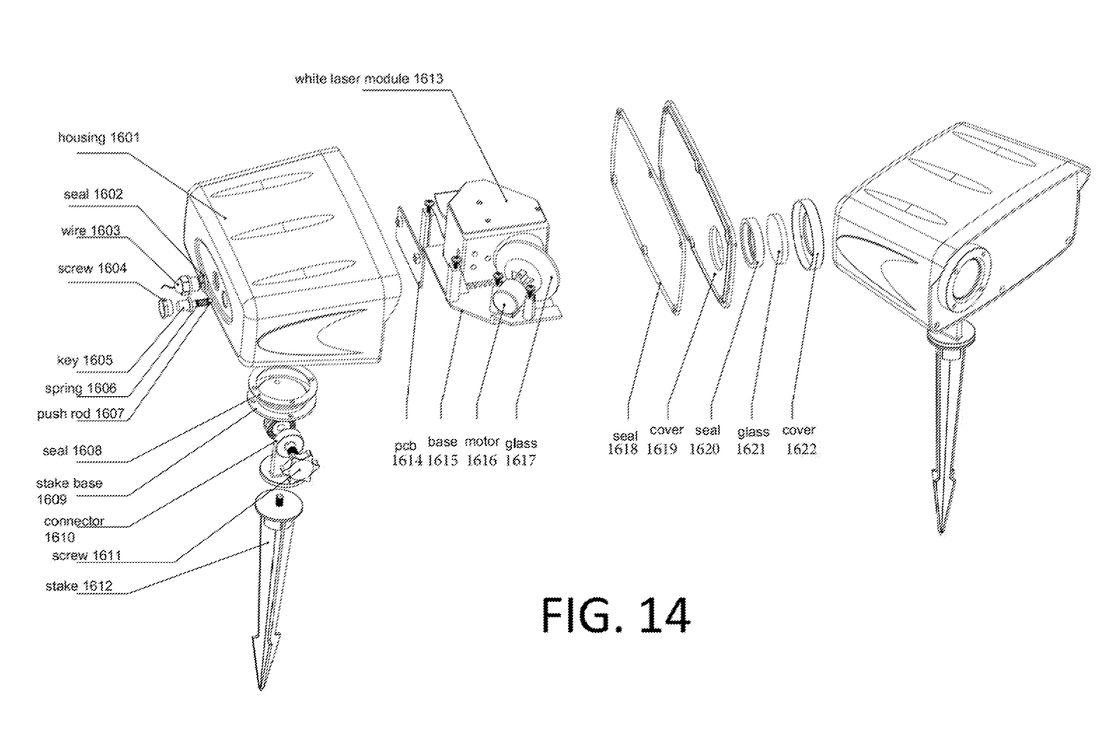

FIG. 14 shows exploded and unexploded views of an exemplary illuminating/lighting apparatus according to one embodiment of the present invention. A white laser module 1613, itself including a light source generating a blue-colored light that passes through a phosphorus filter to transform the blue light into a white light as described herein, may be controlled by a printed circuit board (“pcb”) 1614, affixed to a base 1615, while a glass 1617 is rotated or otherwise moved by a motor 1616 to create movement of light at the projection target. The light reflected by or passing through the glass 1617 proceeds to travel through a seal 1618 of the housing 1601, a cover 1619 and seal 1620, glass 1621, and cover 1622 to ultimately arrive at a projection target. The housing 1601 can include a hole sealed with a seal 1602, through which hole projects a wire 1603 (such as may be used for powering and/or controlling the illuminating/lighting apparatus), a push rod 1607 associated with a screw 1604/key 1605/spring 1606 apparatus. The underside of the housing is connected to a seal 1608, which is connected to a stake base 1609, which is connected to a connector 1610 and screw 1611 assembly (used to adjust the angle of inclination of the housing 1601 and components therein), which is connected to a stake, which may be used to secure the illuminating/lighting apparatus to the ground. It will be understood that, alternatively or in addition to the white laser module 1613 containing the phosphorus filter, the phosphorus filter may be placed at or in the vicinity of (which will be understood to include being incorporated as part of) glass 1617, seal 1618, cover 1619, seal 1620, glass 1621, or cover 1622.

The embodiments and examples shown above are illustrative, and many variations can be introduced to them without departing from the spirit of the disclosure or from the scope of the appended claims. For example, elements and/or features of different illustrative and exemplary embodiments herein may be combined with each other and/or substituted with each other within the scope of the disclosure. For a better understanding of the disclosure, reference should be had to the accompanying drawings and descriptive matter in which there is illustrated exemplary embodiments of the present invention.

1. A lighting apparatus, comprising:
a light source generating a blue-colored light;
a phosphorus filter transforming the blue-colored light into white light;
a light dispersing element receiving the blue-colored light or the white light and projecting an output, the output, when reaching a target surface, includes a plurality of discrete points of light.

2. The light apparatus of claim 1, wherein the light dispersing element is parabolic.

3. The light apparatus of claim 1, wherein the light dispersing element includes a faceted parabolic reflector.

4. The light apparatus of claim 1, wherein the light source includes a laser.

5. The light apparatus of claim 1, wherein the light source includes a plurality of lasers.

6. The light apparatus of claim 1, wherein the light source includes an LED.

7. The light apparatus of claim 1, wherein the light source includes a plurality of LEDs.

8. The light apparatus of claim 1, wherein the phosphorus filter includes a fluorescent phosphorus-coated optical element.

9. The light apparatus of claim 1, wherein the phosphorus filter includes a phosphorus-coated film.

10. The light apparatus of claim 1, wherein the phosphorus filter includes a phosphorus film.

11. The light apparatus of claim 1, wherein the light dispersing element receives the blue-colored light and the output projected from the light dispersing element passes through the phosphorus filter before reaching the target surface.

12. The light apparatus of claim 1, wherein the light dispersing element receives white light that has passed through the phosphorus filter.

13. The light apparatus of claim 12, wherein the phosphorus filter is disposed at or in the vicinity of or incorporated into the light source.

14. The light apparatus of claim 1, wherein the light source and the phosphorus filter are integrated into a monolithic package.

15. The light apparatus of claim 1, wherein the phosphorus filter is disposed at or in the vicinity of or incorporated into the light dispersing element.

16. The light apparatus of claim 1, wherein the light dispersing element comprises diffraction gratings.

17. A method for creating a plurality of discrete points of light on a target surface using a light apparatus including a light source and a phosphorus filter and a light dispersing element, the method comprising:
generating a light using the light source, the generated light including a blue-colored light;
transforming the light into white light by passing the light through a phosphorus filter; and
causing the light to be incident on the light dispersing element, such that the light dispersing element disperses the light and creates a plurality of individual discrete points of light on the target surface.

18. The method of claim 17, wherein the light is blue-colored when it is incident on the light dispersing element and the light dispersed from the light dispersing element passes through the phosphorus filter before reaching the target surface.

19. The method of claim 17, wherein the light is white when it is incident on the light dispersing element and has passed through the phosphorus filter.

20. The method of claim 19, wherein the phosphorus filter is disposed at or in the vicinity of or incorporated into the light source.
